(19) United States
(12) Patent Application Publication
(10) Pub. No.: US 2026/0117415 A1
(43) Pub. Date: Apr. 30, 2026

(54) Systems and Methods for Modifying Crystal Growth Processes

(71) Applicant: Wolfspeed, Inc., Durham, NC (US)

(72) Inventors: Matthew David Conrad, Cary, NC (US); Michael Anthony Fusco, Wake Forest, NC (US); Ramya Lakshmi Gurunathan, Cary, NC (US); Wyatt Witzen, Cary, NC (US); Jason William Leon Witry, Bahama, NC (US); Matthew Alden Howey, Cary, NC (US); Jerome Hugh Lazarczyk, Raleigh, NC (US); Valeri Fedorovich Tsvetkov, Durham, NC (US)

(21) Appl. No.: 18/933,728

(22) Filed: Oct. 31, 2024

(51) Int. Cl. C30B 23/00

(52) U.S. Cl. CPC C30B 23/002

(57) ABSTRACT

A semiconductor crystal control system for modifying a crystal growth process of silicon carbide is provided. The system can obtain one or more crystal growth parameters associated with growing a semiconductor crystal in a crystal growth assembly. The system can determine, based on the one or more crystal growth parameters, a predicted growth condition. The system can modify a crystal growth process based at least in part on the predicted growth condition.

### FIELD

The present disclosure relates generally to semiconductor crystals and semiconductor crystal fabrication.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

### SUMMARY

Aspects and advantages of embodiments of the present disclosure will be set forth in part in the following description, or can be learned from the description, or can be learned through practice of the embodiments.

In an aspect, the present disclosure provides an example method that includes obtaining one or more crystal growth parameters associated with growing a semiconductor crystal in a crystal growth assembly. The method includes determining, based on the one or more crystal growth parameters, a predicted growth condition. The method includes modifying a crystal growth process based at least in part on the predicted growth condition.

In an aspect, the present disclosure provides an example semiconductor crystal control system that includes one or more computer readable storage devices configured to store computer-executable instructions and one or more hardware computer processors in communication with the one or more computer readable storage devices. The one or more hardware computer processors are configured to execute the computer-executable instructions to obtain one or more crystal growth parameters associated with growing a semiconductor crystal in a crystal growth assembly and determine, based on the one or more crystal growth parameters, a predicted growth condition. The instructions can be configured to modify a crystal growth process based at least in part on the predicted growth condition.

In an aspect, the present disclosure provides an example method for training a machine-learning model. The method includes obtaining one or more crystal growth parameters associated with growing a semiconductor crystal in a crystal growth assembly and generating perturbations of at least one of the one or more crystal growth parameters. The method includes causing a randomized dropout of neural network connections associated with the one or more crystal growth parameters assigning a weight to one or more of the neural network connections.

In an aspect, the present disclosure provides an example method includes obtaining one or more crystal growth parameters associated with growing a semiconductor crystal in a crystal growth assembly and generating a plurality of predicted growth conditions using the one or more crystal growth parameters. The method includes selecting a target predicted growth condition and modifying, based on the target predicted growth condition, a crystal growth process based at least in part on the predicted growth condition.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example semiconductor crystal control system for modifying a semiconductor crystal according to example aspects of the present disclosure;

FIG. 2A is a cross sectional schematic diagram of an example crystal growth assembly adapted for use in a seeded sublimation growth process of the type contemplated by certain embodiments of the disclosure, according to example aspects of the present disclosure;

FIG. 2B is another example cross sectional diagram of an example crystal growth assembly that includes an inlet for introducing a dopant to the reaction crucible, according to example aspects of the present disclosure;

FIG. 2C is another example cross sectional diagram of an example crystal growth assembly that includes a continuous feed PVT (CF-PVT) system, according to example aspects of the present disclosure;

FIG. 3A depicts an example process for modifying a semiconductor crystal recipe, according to example aspects of the present disclosure;

FIG. 3B shows another example process, according to example aspects of the present disclosure;

FIG. 4A depicts an example process for modifying recipes for semiconductor crystals according to examples aspects of the present disclosure;

FIG. 4B depicts an example process for modifying semiconductor crystal recipes according to examples aspect of the present disclosure;

FIG. 4C depicts an example process for modifying semiconductor crystal recipes according to examples aspect of the present disclosure;

FIG. 4D shows another exemplary process of training and/or inferring using a machine learning model, according to some embodiments.

FIG. 4E depicts another example process using a deep neural network.

FIG. 5 shows an example yield-height plot that may be developed using a large set of recipes;

FIG. 6 depicts a flow chart diagram of an example method according to example embodiments of the present disclosure;

FIG. 7 depicts a flow chart diagram of an example method according to example embodiments of the present disclosure;

FIG. 8 depicts a flow chart diagram of an example method according to example embodiments of the present disclosure;

FIG. 9 depicts a block diagram of an example computing system 1000 that can be used to implement systems and methods according to example embodiments of the present disclosure;

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to systems for growing semiconductor crystals, such as crystalline silicon carbide (SiC) (e.g., single crystal SiC). In some SiC growth processes, the reaction crucible is made of carbon (including, for example graphite and/or other carbon materials) and is heated using an inductive or resistive heating technique. The heating coils and associated insulation are carefully positioned in relation to the reaction crucible to establish and maintain a desired thermal gradient. Source material, such as powdered SiC, is commonly used in conjunction with vertically oriented or horizontally oriented reaction crucibles. The powdered SiC is retained in a lower portion of the reaction crucible and the seed material is positioned in an upper portion of the reaction crucible during the PVT process.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

Single crystal silicon carbide (SiC) has proven to be a very useful wafer material in the manufacture of such semiconductor devices. Due to its physical strength and excellent resistance to many chemicals, SiC may be used to fabricate very robust substrates adapted for use in the semiconductor industry. SiC has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

SiC crystalline material may be produced using various seeded sublimation growth processes. In a typical SiC growth process, a seed material and source material are arranged in a reaction crucible which is then heated to the sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it condenses to grow a bulk crystalline boule. This type of crystalline growth process is commonly referred to as physical vapor transport (PVT) process.

A resulting SiC boule may then be sliced using into wafers, and the individual wafers may then be used as seed material for a seeded sublimation growth process, or as substrates upon which a variety of semiconductor devices (e.g., power semiconductor devices and optical applications, such as LEDs, windows, photo-diodes, etc.) may be formed.

Growth of semiconductor crystals, such as SiC can involve variations in yield when compared to a height of the boule. A quality of the SiC crystal can vary along the height of the boule. As used herein, “quality” of the SiC crystal may refer to various aspects of a crystal that increase yield of the crystal and may refer, for example, to dislocation density, micropipes distribution, and other measurable descriptors associated with the crystal. Discrepancies in crystal quality may be due to changes or variations in growth conditions as the process progresses. For example, temperature gradients may shift slightly or impurities may accumulate, leading to defects in certain regions of the boule. The lower and upper parts of the boule might exhibit more defects than a middle section. This can be because as the height of the boule increases, thermal stress can build up due to temperature differentials within the crystal. This can lead to cracking or other structural issues, particularly near the top of the boule. Accordingly, taller boules may also experience significant variations in temperature and gas flow dynamics, leading to non-uniform growth rates and increased defect density in certain areas.

Moreover, impurities and/or dopants may distribute unevenly as the boule grows taller, leading to non-uniform electrical properties. These variations can affect the number of wafers (e.g., yield) that meet a minimum quality requirement for semiconductor applications.

A yield-height curve can describe how the proportion of high-quality wafers (yield) varies a the height of the SiC boule. This curve shows higher yields in the middle sections and lower yields near the top and bottom. Achieving a yield-height curve that is more like a plateau, with steep ends and a high, flat yield in the middle can be advantageous as it represents a high yield relative to a height of the boule. By increasing the growth process while reducing defects and maintaining consistent crystal quality throughout the boule, a total yield of high-quality wafers from each boule can be achieved.

Various recipes may be employed to grow the boules. The recipes may include one or more crystal growth parameters associated with growing a semiconductor crystal in a crystal growth assembly, such as a crystal growth assembly. Many crystal growth parameters can be tracked and modified for different recipes, and a large set of combinations of such crystal growth parameters exists. Accordingly, it can be essentially impossible to find recipes that achieve target (e.g., maximum) yield-growth curves by simply testing various parameters in different degrees with each other.

Accordingly, it may be valuable to employ machine learning techniques in analyzing the benefits and weaknesses of various combinations of recipes. Various embodiments described herein can take advantage of various benefits to help ensure that predicted results (e.g., predicted growth condition(s)) generated by the machine learning model. Example benefits described herein include providing small perturbations to inputs. This can provide the system with information about the sensitivity and/or robustness of the model's predictions. By introducing small changes to the input data, how much the prediction varies can be determined, which reveals the model's robustness. By providing small perturbations, the system can identify one or more edge cases and/or potential weaknesses in the model's decision-making process.

Another technical benefit of one or more of the models described herein is the ability to randomly sever some connections in the neural network during training, a process called dropout uncertainty. By severing neural connections, the system can prevent overfitting by ensuring that the model doesn't become too reliant on specific paths within the network. It also provides a measure of uncertainty in the model's predictions by simulating multiple versions of the model. This can be particularly valuable since boule growth can be risk-sensitive, and understanding the confidence level of a prediction is valuable, as described below.

Another technical benefit of one or more embodiments described herein is the ability for certain models to train ensembles. Ensemble training involves training multiple models with different initializations of weights and then combining their predictions. As with dropout uncertainty, ensemble training reduces the likelihood of overfitting and improves the ability of the model to generalize its predictions to other recipes. The variance in predictions across the ensemble can provide insights into the model's uncertainty, enhancing the reliability of the predictions.

In some embodiments, the models can test hypotheses of a predicted recipe. Hypothesis testing allows for the validation of certain relationships within the data (e.g., crystal growth parameters). This may have an additional benefit of making trends and patterns more readable for human users. Because the models can test the relationships between input variables (e.g., crystal growth parameters), hypothesis testing can confirm or refute potential causal connections, leading to more trustworthy models.

To achieve these benefits, systems described herein may include one or more features from gradient models like deep neural networks (DNNs), Bayesian neural networks (BNNs), a random forest model, deep ensembles, convolutional neural networks (CNNs), recurrent neural networks (RNNs), and other models. Models like DNNs can use gradient-based methods (e.g., saliency maps, integrated gradients) to assess how small perturbations affect predictions, highlighting sensitivity within the model. Additionally or alternatively, BNNs can inherently incorporate uncertainty into predictions. Techniques like variational inference can be used with dropout to simulate the effect of Bayesian modeling, making predictions that include uncertainty estimates.

Example aspects of the present disclosure provide systems and methods for inspection and characterization of semiconductor crystal and/or recipe features. The systems and methods may include one or more models described herein. For instance, systems and methods according to some example aspects of the present disclosure may obtain crystal growth parameters associated with a semiconductor crystal and detect one or more features associated with the semiconductor crystal and/or the crystal growth parameters using a trained model, such as an inspection model. An example inspection model includes a stabilized learning generative adversarial network (SLGAN) trained inspection model. In some implementations, the one or more features may be detected during a recipe or fabrication process that, based on the detected one or more features, may be modified, halted, or otherwise reconfigured. The one or more features may include a predicted growth condition of the semiconductor crystal.

To detect the one or more features associated with a semiconductor crystal, data associated with the semiconductor crystal may be provided to a computer implemented model (e.g., inspection model). In some examples, the computer-implemented model includes one or more machine learned models trained, at least in part, with an DNN, CNN, BNN, and/or a SLGAN. Various trained machine-learned models may be incorporated into the inspection model such as autoencoder models, image translation models, feature detection models, computer vision models, and/or any other machine learned model(s) which may assist in or perform inspection of semiconductor crystals.

Embodiments herein can obtain one or more crystal growth parameters associated with growing a semiconductor crystal in a crystal growth assembly and determine a predicted growth condition based on the one or more crystal growth parameters. The system can modify a crystal growth process based at least in part on the predicted growth condition. The system may determine a confidence level that the semiconductor crystal will satisfy one or more growth criteria. Based on the confidence level, the system may cause the crystal growth assembly to modify the one or more crystal growth parameters.

As used herein, “crystal growth parameters” broadly includes any aspect of crystal growth that may influence or otherwise relate to a height, yield, quality, or other feature of the semiconductor crystal growth. A “recipe” can broadly refer to any combination and/or arrangement of crystal growth parameters used to grow a semiconductor crystal. Example crystal growth parameters include, but are not limited to: a crystal weight, a crystal convexity, a crystal resistivity, a number of defects in the semiconductor crystal, a topography of the semiconductor crystal, a type of a crucible of the crystal growth assembly, a type of a grower of the crystal growth assembly, a process condition, an age of the crucible, an age of the grower, an age of coils of the grower, an age of insulation of the grower, a temperature of water associated with growing the semiconductor crystal, a power type, a crystal growth rate, a crystallographic orientation, a purity, a surface quality, an optical property of the semiconductor crystal, and/or a hardness of the semiconductor crystal. For example, an x-ray source may be used to determine one or more properties of the semiconductor crystal.

A crystal growth assembly can include a crucible (e.g., reaction crucible) and a grower. A grower may alternatively be referred to as a seed holder in some embodiments. A crystal growth assembly may grow a semiconductor crystal. A semiconductor crystal control system can measure an actual growth condition of the semiconductor crystal and make modifications to the recipe based on the actual growth condition. For example, one or more crystal growth parameters of the recipe may be modified. For example, modifying the crystal growth process can include modifying one or more of: a temperature of a grower, a flow of gas within the crystal growth assembly, a doping within the semiconductor crystal, a time of the semiconductor crystal within the grower, a placement of the semiconductor crystal within the grower, a pressure within the grower, or a position of a crucible of the crystal growth assembly relative to the grower.

One example consequential crystal growth parameter for the functionality of the semiconductor crystal properties includes a concentration of nitrogen within the semiconductor crystal. Achieving the proper nitrogen concentration in the semiconductor crystal can improve many aspects of the crystal, including electrical properties, material quality, thermal properties, optical properties, and crystal performance.

Nitrogen is commonly used as an n-type dopant in SiC, making the material conductive. The concentration of nitrogen directly affects the electrical conductivity of the SiC crystal. Too little nitrogen might not provide enough free electrons for the desired level of conductivity, while too much can lead to excessive free carriers, which might increase leakage currents and degrade device performance. Precise control of nitrogen concentration allows the resistivity of the SiC material to be tuned. Because different applications require different levels of conductivity, achieving the correct nitrogen concentration can be valuable for optimal device operation.

The proper incorporation of nitrogen into the SiC lattice can help avoid introducing defects or creating unwanted levels of impurities. Additionally or alternatively, uniform nitrogen distribution within the SiC crystal can help ensure more consistent performance across the entire material. Non-uniform doping can lead to localized areas with different electrical properties.

A proper nitrogen concentration helps the semiconductor crystal to efficiently dissipate heat during operation. Moreover, nitrogen doping can influence the optical properties of SiC by altering its bandgap. A proper nitrogen concentration helps in fine-tuning these optical properties to meet specific application requirements. Additionally, proper doping of nitrogen can promote a degree of electrical and material properties to achieve high breakdown voltages.

Incorporation of nitrogen in the bulk semiconductor crystals during the growth process is a function of nitrogen in the vapor phase, temperature f the growth front, nitrogen concentration in the source material (e.g., source powder), and/or a crystal growth rate. Embodiments described herein can modify a concentration of nitrogen by modifying a partial pressure of nitrogen in a gas within the crystal growth assembly, and/or by modifying a temperature of a crystal growth front of the semiconductor crystal. Embodiments described herein can create and/or modify a recipe to adjust nitrogen flow into the reactor during the growth process. Additionally or alternatively, the systems described herein can ramp a special bottom temperature (e.g., powder temperature) for growth of long, high-quality crystals.

The solubility of SiC in a wafer resistivity of about 0.022 Ohm-cm can be described as:

$$N = A \cdot {P}^{a} {e}^{\frac{Q}{RT}} \qquad ( 1 )$$

where N is a concentration of nitrogen in the crystal, A and a are constants, P is a partial pressure of nitrogen in the vapor, Q is an effective energy of nitrogen incorporation in SiC, R is the universal gas constant, and T is the temperature of the crystal growth front. A resistivity r of a SiC wafer can be described as follows:

$$r = \frac{b}{N} \qquad ( 2 )$$

where b is a constant. Fitting parameters A, a, b, and Q can be found using the embodiments described herein. These crystal growth parameters can be process specific and may depend in part on other crystal growth parameters, such as growth rate, crucible permeability, nitrogen concentration in the crucible components, and/or a presence of any chemical compounds that may reduce an activation energy for nitrogen incorporation.
By combining equations (1) and (2), a final equation for predicting a resistivity distribution in growing low-convexity crystals in a C direction can be described as follows:

$$r = \frac{b}{A} \cdot {P}^{- a} {e}^{\frac{- Q}{RT}} \qquad ( 3 )$$

Using the equations above in the embodiments described herein, recipes for uniform doping of bulk SiC crystals can be developed that a achieve an error rate between predicted resistivity and measured resistivity in the semiconductor crystal to less than about 5% and in some embodiments less than about 3%. Additionally or alternatively, embodiments described herein can use machine learning to achieve an accuracy of prediction of the resistivity of the wafers vs some crystal growth parameters with can predict the resistivity of the wafer with accuracy of around 97% of a measured resistivity.

The features described above may be obtained by implemented one or more trained machine learned models. In some instances, the model may include one or more networks (e.g., neural networks) trained with regulated learning rates. A generative adversarial network (GAN) may include a discriminator network and a generator network that train based on the output of each other. The discriminator network and/or the generator network may be neural networks, such as deep neural networks, in some examples.

The learning rates of the one or more aspects of neural networks may be regulated based on, for example, an adversarial ratio. The adversarial ratio may be based on a ratio of the loss associated with a generator network relative to the loss associated with a discriminator network. The adversarial ratio may be monitored in accordance with one or more threshold values (e.g., thresholds) to modify the learning rate of one or more of the neural networks within the model, such as the discriminator network or the generator network.

In some examples, the trained model within the inspection model may be an autoencoder model including an encoding portion and a decoding portion, each with one or more machine-learned models. Any input to the inspection model may be provided to the encoding portion of the autoencoder model to generate an encoding of the input. The encoding model can be any suitable encoding or encoder model. An encoding model can receive various types of input (e.g., image data, alphanumerical data, etc.) and, in response to receipt of the input data, produce an encoding as output. The encoding can be a representation of the input variables in a machine-encoded format (e.g., a numerical format). In some examples, the encoding may not be human-readable. However, characteristics and trends among the input data may be represented in characteristics of the encoding. In particular, the encoding model can be trained to produce encodings that represent characteristics of the input data by training the encoding model end-to-end with a decoding or decoder model. For instance, in some examples, the encoding of the input workpiece data may be indicative of one or more features, feature distributions, anomalies, or similarities of the semiconductor crystal.

The decoding model can be configured to receive an encoding as input and, in response to receipt of the encoding as input, produce output in a human-intelligible or other suitable format, such as image data, alphanumerical data, classification data, or other suitable data. In some implementations, such an arrangement may be referred to as an “autoencoder.” However, in some implementations, the encoding model and decoding model may not necessarily be related or be part of a common model schema such as an autoencoder. For instance, the encoding model and the decoding model may be independent models having separate networks (e.g., neural networks). In some examples, the encoding model may be any suitable machine learned model that is trained to produce encoding that represents input data. The model can have any number of parameters without deviating from the scope of the present disclosure. The model can have various model architectures (e.g., any number convolutional layers, transformer layers, etc.) without deviating from the scope of the present disclosure. In some implementations, the autoencoder model may be trained, at least in part, using the SLGAN. For instance, the decoding portion of the autoencoder (e.g., decoding model) may be trained using the discriminator network of the SLGAN.

To provide for outputting encodings that reflect the characteristics of the semiconductor crystals, the method can include training the machine-learned encoding model on a batch of training data. The training data can include input data corresponding to one or more additional semiconductor crystals. The training data can include, for example, one or more crystal growth parameters, recipes, and/or additional inputs for the additional semiconductor crystals. In some implementations, the machine-learned encoding model can be trained end-to-end with a machine-learned decoding model. For instance, the machine-learned decoding model can be a decoding network having a separate neural network from the machine-learned encoding model.

In some embodiments, the machine-learned models can include one or more physics equations built into a neural network. For example, the models can include Physics-Informed Neural Networks (PINNs), which can include a type of machine learning model that incorporates physical laws (e.g., differential equations) into the learning process. The PINNs can be trained using data generated by physical simulations in addition to or alternative to real-world experiments. Such simulation data can solve equations related to the recipe. PINNs help by learning from simulation data from simulated recipes to predict otherwise hard-to-obtain inputs in a real system.

In some embodiments, the model can include a Graph Neural Network (GNN) that can include and/or use graph-structured data. The GNNs can be configured to process data represented as nodes (vertices) and edges (connections) between them. The GNN can exchange data between neighboring nodes in a graph. Each node can aggregate information from neighbor (e.g., adjacent) nodes. The GNN can learn node representations (e.g., features that describe each node) and/or graph-level representations (e.g., features describing the entire graph) in a way that reflects the graph's structure and/or the features of the nodes/edges. The GNN can use the learned representations for node classification, link prediction, and/or graph classification.

The model may include a transformer model, which can be helpful in natural language processing, speech processing, computer vision, reinforcement learning, and/or other aspects of the growth recipe. The transformer can provide one or more weights associated with how to weight each variable in the recipe relative to learned outputs.

In some embodiments, the model includes a Recurrent Neural Networks (RNNs), a Long Short-Term Memory (LSTM) networks, and/or multi-modal models that include a plurality of types of models described herein. RNNs and LSTM networks can analyze sequential data, making them helpful in identifying time series analysis associated with the recipes. For example, the system can monitor the machinery, sensors, and/or other elements of the crystal growth assembly 112. The data can be used by the LSTM or other aspect of the trained model 160 to update future operational data. The model can identify unusual and/or anomalous patterns in real-time.

In some implementations, the autoencoder may be a deep convolutional multiscale variational autoencoder (MS-VAE). The deep convolutional MS-VAE may be an autoencoder that is convolutional, e.g., that includes one or more convolutional neural networks. A convolutional neural network is a type of feed-forward neural network that applies multi-dimensional filters (or “kernels”) at inputs and/or links, weighing multiple prior nodes when advancing through layers.

To achieve some of the benefits described herein, various aspects of the crystal growth recipe may be modified. For example, the source material can be shaped to obtain a desired vapor flow/local vapor pressure relative to the seed/growing crystal surface. For example, it may be desired to have increased sublimation in the center of the seed/growing crystal and less sublimation on its periphery. Therefore, the source can be designed to have increased surface area in central portions relative to peripheral portions. Such vapor flow/pressure characteristics can change to modify the growth process, thereby controlling the shape of the growing crystal. Such features are described in more detail below with reference to the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, typical embodiments are described and, although specific terms are employed, they are used in a generic and descriptive sense only and not for purposes of limitation of the scope set forth in the following claims.

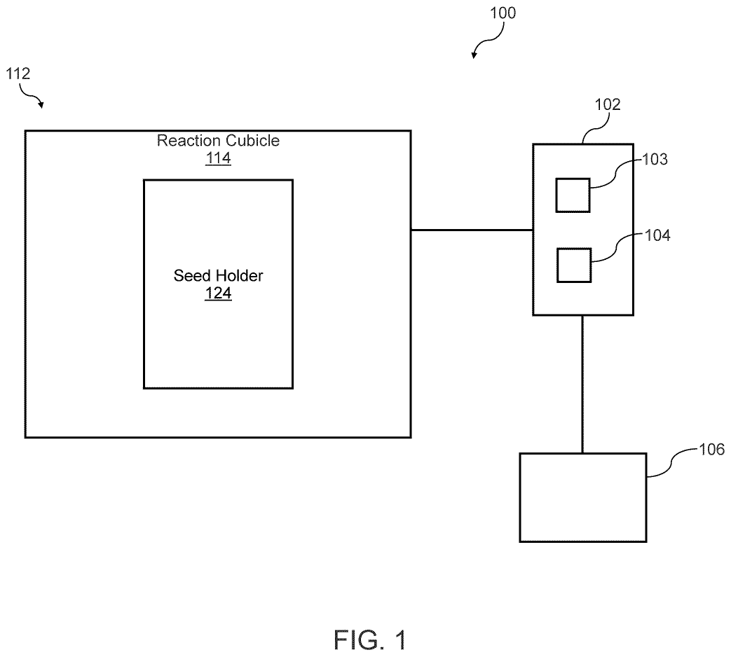

FIG. 1 depicts an example semiconductor crystal control system 100 for modifying a semiconductor crystal according to example aspects of the present disclosure. The example semiconductor crystal control system 100 includes a crystal growth assembly 112 configured to modify a recipe. Those of ordinary skill in the art, using the disclosures provided herein, will understand that the semiconductor crystal control system 100 may include more or fewer components without deviating from the scope of the present disclosure. The semiconductor crystal control system 100 may be configured to implement one or more aspects of the present disclosure, such as the processing operations for modifying a recipe for growing a semiconductor crystal, as described herein.

The semiconductor crystal control system 100 can include a crystal growth assembly 112, a controller 102, and/or a computing device 106. The crystal growth assembly 112 can include a reaction crucible 114 and a seed holder 124. The seed holder 124 may be referred to as a grower in some contexts. The reaction crucible 114 can provide a thermal housing in which the semiconductor crystal can be grown. Additional details of example crystal growth assemblies 112 are provided below. The seed holder 124 can provide a space for the semiconductor crystal to grow within the reaction crucible 114. The seed holder 124 can include source material (e.g., powder) that is configured to encourage growth of the crystal boule. Together the reaction crucible 114 and the seed holder 124 can grow the semiconductor crystal according to one or more crystal growth parameters provided to the crystal growth assembly 112 by the controller 102.

The controller 102 can receive information related to one or more recipes and/or cause the crystal growth assembly 112 to grow a semiconductor crystal according to the one or more recipes. For example, the controller 102 can receive and/or determine one or more crystal growth parameters associated with growing a semiconductor crystal in the crystal growth assembly 112. In some embodiments, the controller 102 receives current crystal growth parameters, which may include a current recipe, from the crystal growth assembly 112. Additionally or alternatively, the controller 102 may receive the crystal growth parameters from a separate computing device 106. The computing device 106 may be connected to the controller 102 via a wired and/or wireless connection. Additionally or alternatively, the controller 102 may be connected to the crystal growth assembly 112 via a wired and/or wireless connection. The controller 102 can determine a predicted growth condition of the semiconductor crystal, based on the one or more crystal growth parameters. For example, the controller 102 may predict a particular convexity, height, yield, etc. associated with the semiconductor crystal. The controller 102 can modify a crystal growth process, which may include a recipe and/or one or more crystal growth parameters, based at least in part on the predicted growth condition. For example, if the semiconductor crystal is predicted to have a smaller yield than a threshold yield, then the controller 102 may cause the crystal growth assembly 112 to modify one or more of the crystal growth parameters.

In some embodiments, the controller 102 may determine a confidence level associated with a current and/or modified recipe. For example, the controller 102 can determine a confidence level associated with whether the semiconductor crystal will satisfy one or more growth criteria, under the current recipe and/or under a modified recipe.

The controller 102 can include a storage device 103 and/or a processor 104. The controller 102 may include processing circuitry such as one or more processor 104. The storage device 103 may include one or more storage devices and may store computer-readable instructions that when executed by the one or more processors 104 cause the one or more processors 104 to perform one or more control functions, such as any of the functions described herein. In some examples, the one or more storage devices 103 may store the one or more trained machine learned models. Additionally or alternatively, the trained model(s) may be stored on the computing device 106. In some embodiments, the controller 102 sends the one or more crystal growth parameters to the computing device 106 for processing on the prediction of the growth parameters, results of the recipe, and/or recipe recommendation. In some embodiments, the computing device 106 can receive a target growth parameter of the semiconductor crystal from the controller 102. Additionally or alternatively, the controller 102 may receive a target growth parameter from the computing device 106, which may influence how the recipe is modified.

The controller 102 can cause the crystal growth assembly 112 to modify the one or more crystal growth parameters if it determines that the growth criteria are not predicted to be satisfied. The confidence level may be based on a ratio of a predicted crystal yield to a predicted height of the semiconductor crystal. For example, the controller 102 may include a trained model, such as one described herein, to determine a predicted height of the semiconductor crystal, yield, and/or ratio of the two.

The one or more crystal growth parameters can include one or more of: a crystal weight, a crystal convexity, a crystal resistivity, a number of defects in the semiconductor crystal, a topography of the semiconductor crystal, a type of a crucible of the crystal growth assembly 112, a type of a grower (e.g., seed holder) of the crystal growth assembly 112, a process condition, an age of the crucible, an age of the grower, an age of coils of the grower, an age of insulation of the grower, a temperature of water associated with growing the semiconductor crystal, a power type, a crystal growth rate, a crystallographic orientation, a purity, a surface quality, an optical property of the semiconductor crystal, or a hardness of the semiconductor crystal.

In some embodiments, the reaction crucible 114 can include a plurality of crucibles. Additionally or alternatively, the seed holder 124 can include a plurality of seed holders. The crystal growth parameters obtained by the controller 102 can include attributes associated with each of the plurality of crucibles and/or of the seed holders. The controller 102 may assign each of a plurality of crucibles a respective identifier and/or each of the plurality of crucibles a respective identifier. The controller 102 can select a combination of crucible and a seed holder 124 for the crystal growth assembly 112. The controller 102 may determine the predicted growth condition based on which reaction crucible 114 and/or seed holder 124 are being used. In some embodiments, the controller 102 can select a different reaction crucible 114 and/or seed holder 124 when modifying the recipe.

The semiconductor crystal control system 100 may seek to optimize or improve a convexity (e.g., a predicted convexity) of a semiconductor crystal boule. The convexity can refer to the shape of the surface of the semiconductor crystal, specifically how the surface curves outward or inward. The term “convexity” may describe the curvature of the semiconductor crystal's surface at the solid-vapor interface during growth. For example, positive convexity can describe a surface that curves outward, resembling the exterior of a sphere (e.g. convex shape). In crystal growth, positive convexity means the central part of the crystal grows faster than the edges, leading to a dome-shaped surface. By contrast, negative convexity can occur when the surface curves inward, similar to the interior of a sphere (e.g., concave shape). This indicates that the edges of the crystal are growing faster than the center, resulting in a bowl-like surface. The semiconductor crystal control system 100 may be configured to select a recipe that achieves a positive convexity, which can reduce the occurrence of defects, such as cracks, as well as increase a uniformity of dopants throughout the boule. Accordingly, the controller 102 may determine a predicted convexity of the semiconductor crystal. Additionally or alternatively, the controller 102 may determine a predicted growth rate (e.g., of a side, of a center), growth height, and/or other growth aspect of the semiconductor crystal.

As noted above, it may be valuable to encourage a high degree of crystal quality during growth. Accordingly, the controller 102 may reduce a predicted variance in a crystal yield. For example, the controller 102 may implement one or more of the equations described above with regard to nitrogen doping, such as what ratio of nitrogen to powder should exist in the crystal growth assembly 112 during the growth process. The predicted variance may be based on (e.g., within) a height range. The variance in the crystal yield may be a function of the predicted height and/or other predicted growth attribute of the semiconductor crystal.

The controller 102 may predict a growth condition and/or modify one or more of the crystal growth parameters (e.g., the recipe) using a trained model described herein. This may involve generating perturbations of one or more crystal growth parameters to see how sensitive the predicted growth condition is. Additionally or alternatively, the trained model may apply randomized dropout uncertainty, which can include randomly severing some connections in a neural network of the trained model. The controller 102 may generate an ensemble of growth outcomes based on a set of various weights applied to one or more crystal growth parameters and/or layers to determine a variance in the various growth parameter predictions. Additionally or alternatively, the controller 102 can generate a plurality of models, each associated with a different weight assigned to a respective neural network connection. In some embodiments, the system may include validating one or more relationships using hypothesis testing. For example, virtual crucibles with slightly different properties with varied inputs can be used to see how each affects crystal height and/or yield. As another example, virtual powder load weights can be tested to predict various crystal heights and/or yields.

In some embodiments, the controller 102 may measure an actual growth condition of a grown semiconductor crystal. This may occur before generating a modified recipe, in order to gather data to make the predictions using modified data. additionally or alternatively, the actual growth may be after a modified recipe has been applied, in order to see how close the predicted growth parameter was compared to the actual growth parameter. Accordingly, in some embodiments, the controller 102 can compare an actual growth condition of the semiconductor crystal with a predicted growth condition. Modifying the crystal growth process may be based on the comparison of the actual growth condition with the predicted growth condition.

Determining which crystal growth parameter(s) to modify can be valuable to ensure that the modified growth parameter(s) are the ones to be changed and by how much. Which parameters to modify may be based on determining that a predicted height of the semiconductor crystal is outside a target height range. Determining which crystal growth parameter(s) to modify may be based on determining that a predicted variance, within a height range, in a crystal yield as a function of a predicted height of the semiconductor crystal is outside a target variance range.

Modifying the crystal growth process can involve the modification of one or more aspects of the growth process. For example, modifying the crystal growth process can include modifying: a temperature of a grower, a flow of gas within the crystal growth assembly 112, a doping within the semiconductor crystal, a time of the semiconductor crystal within the grower, a placement of the semiconductor crystal within the grower, a pressure within the grower, a position of a crucible of the crystal growth assembly 112 relative to the grower, and/or a flow of nitrogen into the crystal growth assembly 112.

In some embodiments, the controller 102 can receive and/or otherwise obtain a temperature within the crystal growth assembly 112. This may be done during, before, or after a growth process. The controller 102 may modify a flow of nitrogen into the crystal growth assembly 112 based on the temperature within the crystal growth assembly 112. The temperature within the crystal growth assembly 112 may correspond to a temperature of a crystal growth front of the semiconductor crystal. Additionally or alternatively, the controller 102 can modify a concentration of nitrogen within the semiconductor crystal.

The crystal growth parameters can include a variety of parameters, such as a growth rate, a permeability of a crucible of the crystal growth assembly 112, a nitrogen concentration in the crystal growth assembly 112, and/or a concentration of a chemical compound configured to reduce an activation energy for nitrogen incorporation. The controller 102 can modify the concentration of nitrogen by modifying at least one of: a partial pressure of nitrogen in a gas within the crystal growth assembly 112, and/or a temperature of a crystal growth front of the semiconductor crystal.

The controller 102 may send control signals to the various components of the semiconductor crystal control system 100 (e.g., crystal growth assembly 112, one or more sensor(s), etc.) to implement the aspects of the present disclosure described herein. Additionally, the controller 102 may include one or more machine-learned models (e.g., a machine-learned encoding model, autoencoder, feature detection model, etc.) for inspecting and/or classifying of semiconductor crystals, as described herein. As one example, the controller 102 may be, may include, or may be in communication with at least a portion of the computing system computing device 106, which may additionally or alternatively include such models.

As indicated above, in some embodiments, the semiconductor crystal control system 100 may additionally include one or more sensors (not shown) for obtaining data associated with the semiconductor crystal, such as semiconductor crystal classification data. Semiconductor crystal characterization data can include data that provides information associated with the semiconductor crystal, such as topography, roughness, presence of anomalies, doping, thickness, and/or other characteristics. Semiconductor crystal characterization data may include, for instance, a height of the semiconductor crystal, a yield of the semiconductor crystal, and/or details associated with the surface of the semiconductor crystal. In some embodiments, the one or more sensors may include one or more surface measurement lasers that may be operable to emit a laser onto the surface of the semiconductor crystal and scan the surface (based on reflections of the laser) for depth measurements, topography measurements, etc. of the surface of the semiconductor crystal. Other suitable sensors may be used without deviating from the scope of the present disclosure.

In some embodiments, the semiconductor crystal control system 100 may obtain semiconductor crystal data relating to the semiconductor crystal for processing by the machine learning model. As an example, the semiconductor crystal control system 100 may provide the one or more semiconductor crystal growth parameters to the machine learning model as semiconductor crystal data. The machine learning model may include a variety of machine learned models, each with varying capabilities to process the semiconductor crystal data for the semiconductor crystal control system 100.

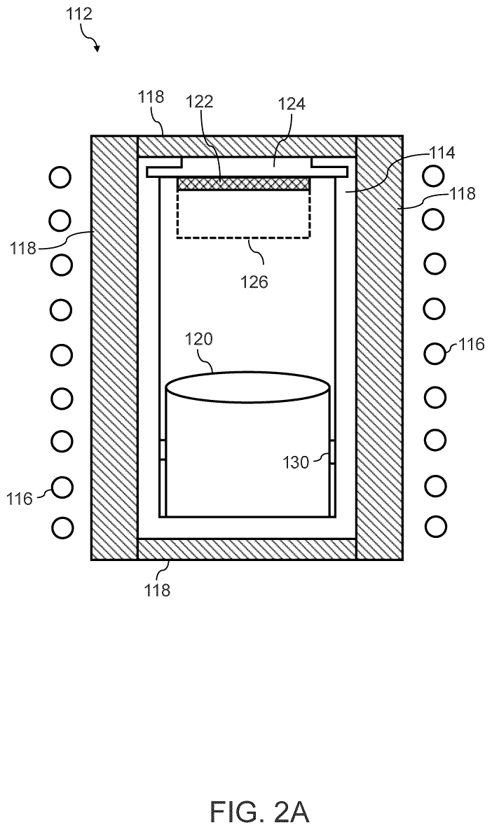

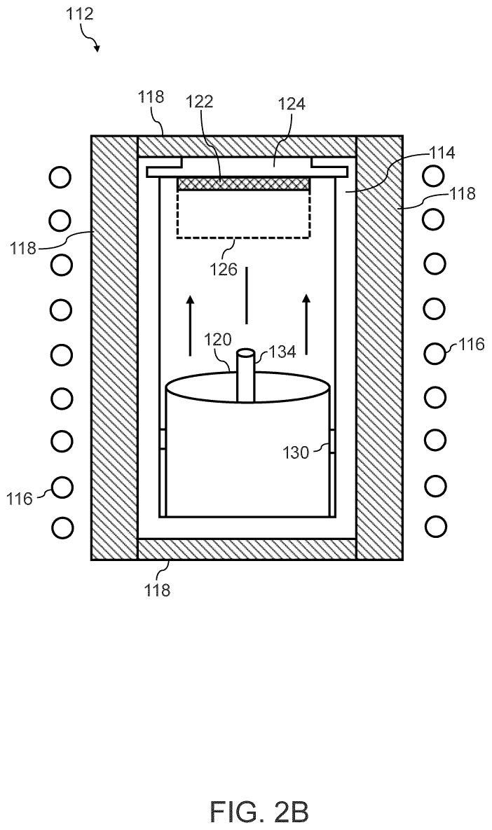

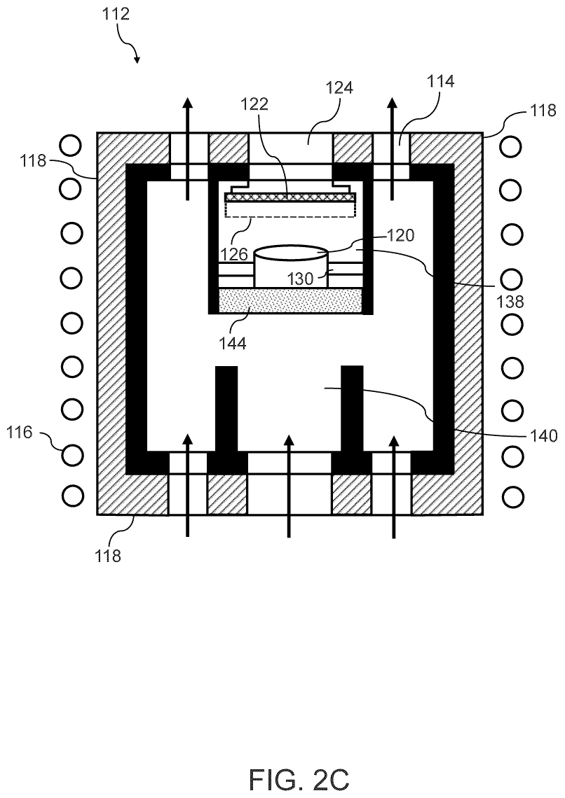

FIG. 2A is a cross sectional schematic diagram of an example crystal growth assembly 112 adapted for use in a seeded sublimation growth process of the type contemplated by certain embodiments of the disclosure. Crystal growth assembly 112 includes a reaction crucible (also referred to as a susceptor or growth cell) 114 and a plurality of induction coils 116 adapted to heat reaction crucible 114 when electrical current is applied. Alternatively, a resistive heating approach may be applied to the heating of reaction crucible 114. Using any competent heating mechanism and approach, the temperature within a furnace housing crystal growth assembly 112 may be controllable. The reaction crucible 114 may be made of graphite.

The furnace housing crystal growth assembly 112 may also include one or more gas inlet and/or gas outlet ports and associated equipment allowing the controlled introduction and evacuation of gas from an environment surrounding reaction crucible 114. The introduction and evacuation of various gases to/from the environment surrounding reaction crucible 114 may be accomplished using a variety of inlets/outlets, pipes, valves, pumps, gas sources, and controllers. It will be further understood by those skilled in the art that crystal growth assembly 102 may further incorporate in certain embodiments a water-cooled quartz vessel.

Reaction crucible 114 may be surrounded by insulation material 118. The composition, size, and placement of insulation material 118 will vary with individual crystal growth assemblies 112 in order to define and/or maintain desired thermal gradients (both axially and radially) in relation to reaction crucible 114. For purposes of clarity, the term, “thermal gradient,” will be used herein to describe one or more thermal gradient(s) associated with reaction crucible 114. Those skilled in the art recognize that “the thermal gradient” established in embodiments of the disclosure will contain (or may be further characterized as having) axial and radial gradients, or may be characterized by a plurality of isotherms.

Prior to establishment of the thermal gradient, reaction crucible 114 is loaded with one or more source materials. As such, the reaction crucible includes one or more portions, as least one of which is capable of holding source material 120, which is represented by a generic cylinder for simplicity but, as further described herein, includes a shaped solid silicon carbide structure. As illustrated in FIG. 2A, source material 120 may be held in a lower portion of reaction crucible 114, as is common for one type of reaction crucible 114.

A seed material 122 may be placed above or in an upper portion of reaction crucible 114. Seed material 122 may take the form of a mono-crystalline SiC seed wafer having a diameter from about 50 to about 300 mm. A SiC single crystal boule 126 will be grown from seed material 122 during the seeded sublimation growth process. The seed material 122 may have a 4H crystal structure, 6H crystal structure, or other crystal structure. The seed material 122 can be on-axis (e.g., end face parallel to the (0001) plane) or off-axis (e.g., end face non-parallel to the (0001) plane). Growth may occur on the silicon face or the carbon face of the seed material 122.

In the embodiment illustrated in FIG. 2A, a seed holder 124 is used to hold seed material 122. Seed holder 124 is securely attached to reaction crucible 114 in an appropriate fashion using conventional techniques. For example, in the orientation illustrated in FIG. 2A, seed holder 124 is attached to an uppermost portion of reaction crucible 114 to hold seed material 122 in a desired position. In one embodiment, seed holder 124 is fabricated from carbon. The attachment of the seed material (e.g., a seed wafer) to a corresponding seed holder within a crystal growth assembly may be made with, for instance, a uniform thermal contact. Various techniques may be used to implement a uniform thermal contact. For example, the seed material may be placed in direct physical contact with the seed holder, or an adhesive may be used to fix the seed material to the seed holder, so as to ensure that conductive and/or radiative heat transfer is uniform over substantially the entire area between the seed and the seed holder.

In some embodiments, the crystal growth assembly may include a second source material. The second source material can be a solid shaped source material according to any of the embodiments described herein or may be another type of silicon carbide vapor source material. The second source material may be located anywhere within the crucible. For example, it may be spaced axially, radially, or concentrically from a first solid source structure.

Further, the crystal growth assembly 112 may optionally include a source material holder 130. The source material holder 130 may be, for example, one or more graphite components within the crucible that brace or support the shaped solid source material. In some embodiments, the source material holder 130 may be attached to the inner walls of the reaction crucible 114, as shown in FIG. 2A.

Each of the features described above may be a crystal growth parameter that may be included in the recipe. For example, a type and/or material of the insulation material 118, a temperature of the induction coils 116, a location of the source material 120, a type and/or material of the seed material 122, and/or a type of the seed holder 124 can be examples of parameters that may be modified by the controller 102.

In another example embodiment, shown in FIG. 2B, crystal growth assembly 112 may be similar to that shown in FIG. 2A, but also includes an inlet 134 for introducing a dopant (e.g., N₂) to the reaction crucible 114. The inlet 134, may be, for example, a tube, pipe, vent, or the like. In some embodiments, the source material 120 may surround the inlet 134. For example, in some embodiments, the solid shaped source material structure may include a channel through which the inlet 134 is provided. In other embodiments, the solid shaped source material structure may include a plurality of subcomponents (attached or detached) which surround the inlet 134. The inlet 134 may be connected to a dopant-containing gas source (not shown) and configured to introduce the dopant-containing gas to the reaction crucible 114. An example of a dopant-containing gas is nitrogen.

In another example embodiment, shown in FIG. 2C, crystal growth assembly 112 may be a continuous feed PVT (CF-PVT) system. In the CF-PVT system, the reaction crucible 114 may include an upper chamber 138 and a lower chamber 140. The upper chamber 138 may include the solid source material 120 and the seed material 122. The upper chamber 138 may be separated from the lower chamber 140 by a foamed structure 144. The foamed structure 144 may be formed, for example, from a gas-permeable graphite foam. The solid source material 120 may be placed on the foamed structure 144 within the upper chamber. A gaseous silicon source (e.g., trimethylsilane diluted in argon) may be supplied to the lower chamber. As the gaseous silicon source flows through the foamed structure 144, it may react with a carbon source within the foamed structure 144 (e.g., graphite) to form silicon carbide. The CF-PVT system combines the PVT process for the growth of single crystals and HTCVD process for the in-situ formation and continuous feeding of high purity polycrystalline source. The CF-PVT system may be particularly useful for growing 3C silicon carbide.

In any of the embodiments shown in FIGS. 2A-2C or any other suitable sublimation growth systems, reaction crucible 114 may be implemented in a number of different shapes and may hold one or more source materials accordingly. Thus, while embodiments of the present disclosure may be illustrated with certain reaction crucible designs, the scope of the present disclosure is not limited to such designs but will find application in different crystal growth assemblys using many different types of reaction crucibles. The source material 120 is a shaped solid structure containing silicon carbide.

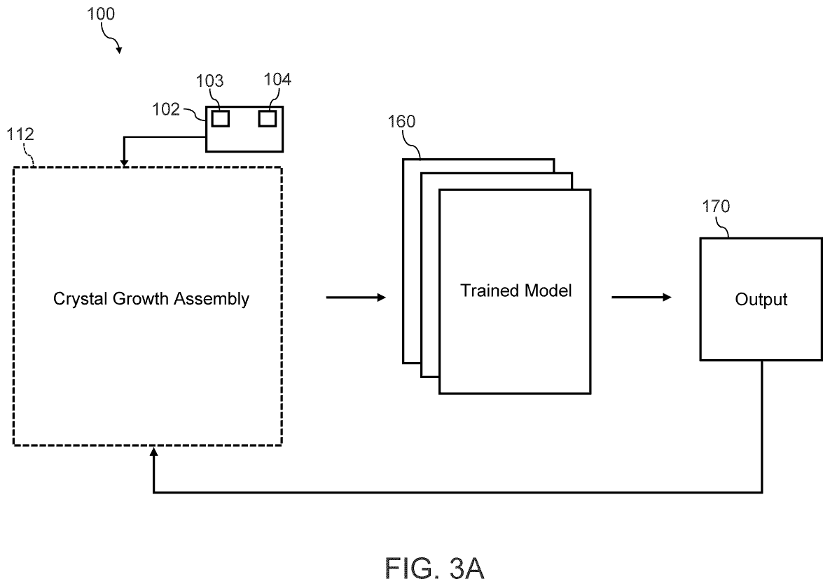

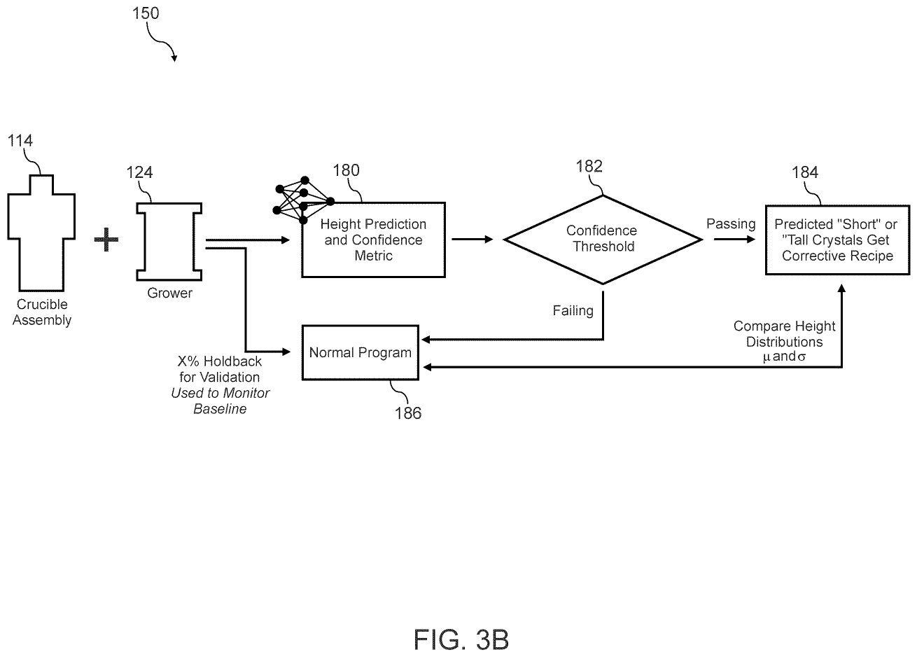

FIG. 3A depicts an example process for modifying a semiconductor crystal recipe, according to example aspects of the present disclosure. The example process includes a semiconductor crystal control system 100 configured to modify a semiconductor crystal, such as a silicon carbide semiconductor wafer. Those of ordinary skill in the art, using the disclosures provided herein, will understand that the semiconductor crystal control system 100 may include more or fewer components without deviating from the scope of the present disclosure. The semiconductor crystal control system 100 may be configured to implement one or more aspects of the present disclosure, such as the processing operations for modifying and/or classifying of semiconductor crystals described herein.

The semiconductor crystal control system 100 can transfer input data (e.g., semiconductor crystal data) to a trained model 160, which can process received input data and produce an output 170 that may include a variety of data associated with one or more characteristics of the semiconductor crystal, one or more crystal growth parameters, and/or a recipe. As examples, the output 170 may be an encoding of said data and/or parameters, a feature detection output, and/or another output described herein. Each type of output 170 may provide information relating to a plurality of characteristics pertaining to the semiconductor crystal and/or an associated growth process. In some embodiments, the output 170 may be used to modify one or more semiconductor growth processes, based on the characteristics of one or more features present within the output 170.

FIG. 3B shows another example process 150, according to some embodiments. The process 150 may be performed by any system described herein, such as the semiconductor crystal control system 100. A reaction crucible 114 and a seed holder 124 can be provided and output one or more crystal growth parameters. At 180, the system can predict a height of a semiconductor crystal growth and/or a confidence metric associated with the predicted height. The predicted height may be based on the reaction crucible 114 and the seed holder 124.

At 182 the process 150 can include checking whether the confidence metric satisfies a confidence threshold. The confidence threshold may include, for example, a minimum height of the semiconductor crystal boule. If the confidence threshold is not satisfied, then the predicted height and/or other data is sent to the nominal program at 186. If the confidence threshold is satisfied, then the process 150 will include modifying a predicted short or tall crystal with a corrective recipe at 184. The corrective recipe will be sent to a nominal program at 186. The nominal program may correspond to a trained model, which may take the data from 186 and develop a proper recipe. Additionally or alternatively, the nominal program may correspond to the instructions stored on the storage device 103 of the controller 102, which may control the recipe of the reaction crucible 114 and/or seed holder 124.

At 186 the nominal program can store and/or execute instructions for a recipe associated with the reaction crucible 114 and the seed holder 124. In some embodiments, the nominal program will send one or more commands to the reaction crucible 114 and/or the seed holder 124 to grow the process according to the recipe, which may have been modified at 184.

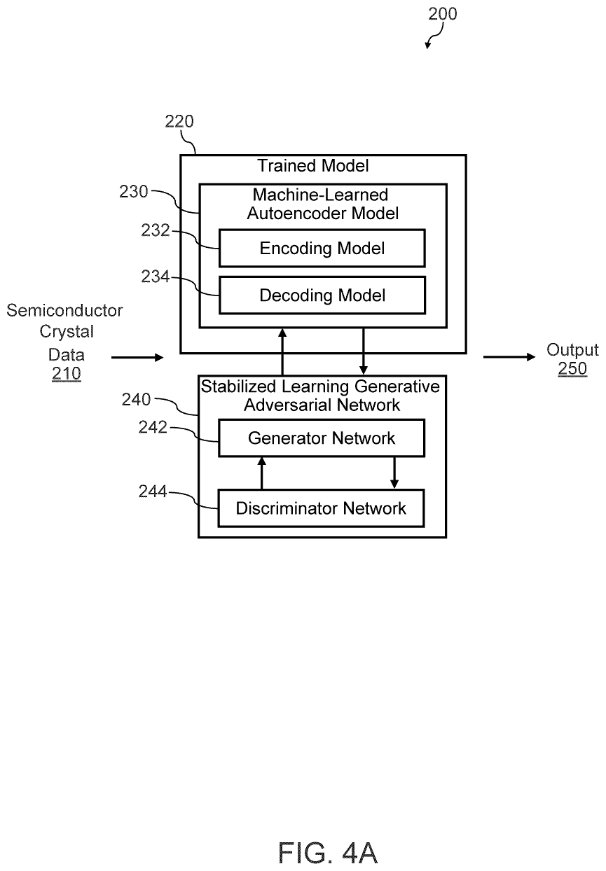

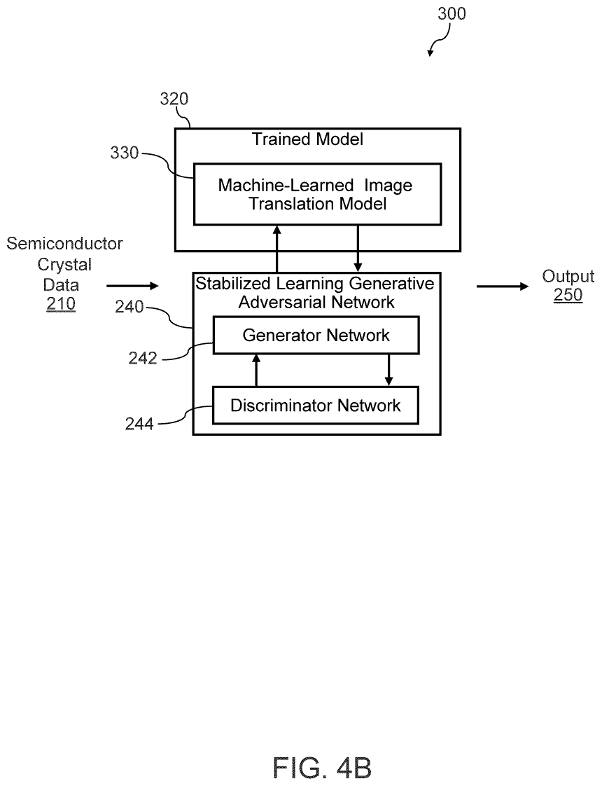

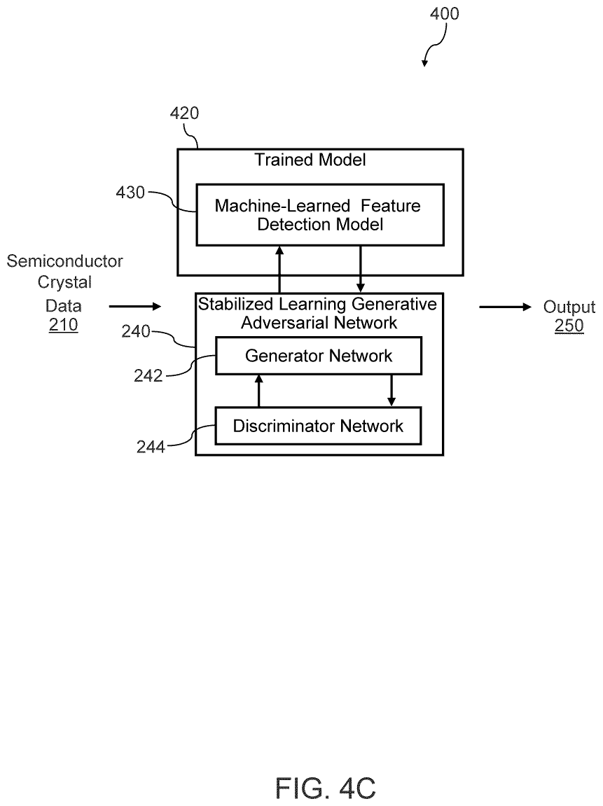

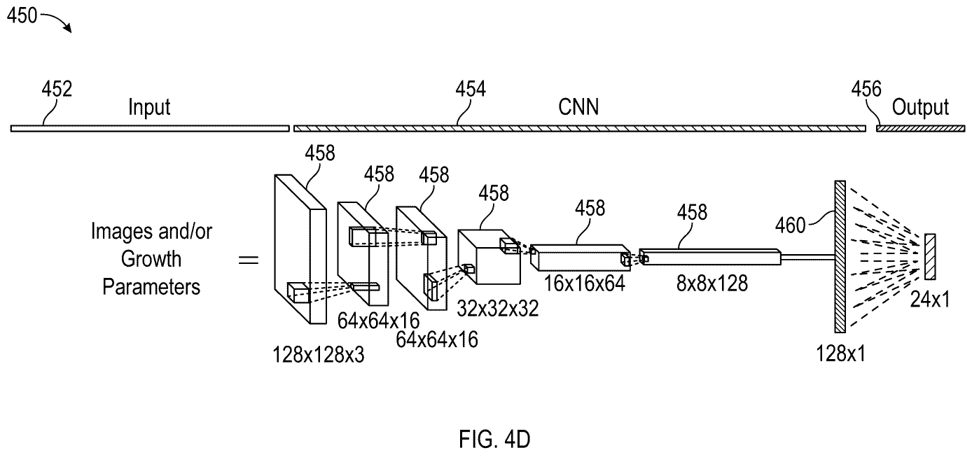

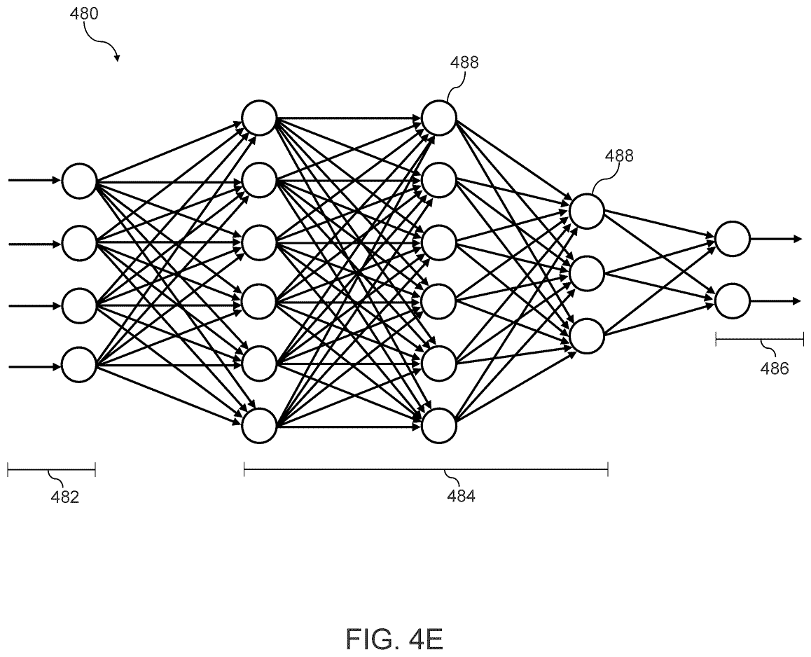

FIGS. 4A-4E depict a variety of processes using various trained models that may be used by the semiconductor crystal control system 100. FIG. 4A depicts an example process 200 for modifying recipes for semiconductor crystals according to examples aspects of the present disclosure. The example process 200 includes processing semiconductor crystal data 210 with a trained model 220 to produce an output 250 associated with one or more characteristics of a semiconductor crystal associated with the semiconductor crystal data 210. The semiconductor crystal data 210 may be a variety of data types and data formats. For instance, the semiconductor crystal data 210 may be recipe data for the semiconductor crystal, such as one or more crystal growth parameters. Once generated, the semiconductor crystal data may be provided to the trained model 220 as input.

As depicted, in some implementations, the trained model 220 may be a machine-learned autoencoder model 230. The autoencoder model 230 may include both an encoding portion 232 (e.g., encoding model(s)) and a decoding portion 234 (e.g., decoding model(s)). Any input to the trained model 220, such as semiconductor crystal data 210, may be provided to the encoding portion of the autoencoder model to generate an encoding of the input. The encoding portion 232 can be any suitable encoding or encoder model. An encoding model can receive various types of input (e.g., image data, alphanumerical data, etc.) and, in response to receipt of the input data, produce an encoding as output. The encoding can be a representation of the input variables in a machine-encoded format (e.g., a numerical format). In some examples, the encoding may not be human-readable. However, characteristics and trends among the input data may be represented in characteristics of the encoding. In particular, the encoding model can be trained to produce encodings that represent characteristics of the input data by training the encoding model end-to-end with a decoding or decoder model. For instance, in some examples, the encoding of the input semiconductor crystal data 210 may be indicative of one or more crystal features (e.g., crystal growth parameters), feature distributions, anomalies, or similarities of a semiconductor crystal.

The decoding portion 234 can be configured to receive an encoding as input and, in response to receipt of the encoding as input, produce output in a human-intelligible or other suitable format, such as image data, alphanumerical data, classification data, or other suitable data. In some implementations, the encoding portion 232 and decoding portion 234 may not necessarily be related or be part of a common model schema. For instance, the encoding portion 232 and the decoding portion 234 may be independent models having separate networks (e.g., neural networks). In some examples, the encoding portion 232 may be any suitable machine learned model that is trained to produce encoding that represents input data. The model can have any number of parameters without deviating from the scope of the present disclosure. The model can have various model architectures (e.g., any number convolutional layers, transformer layers, etc.) without deviating from the scope of the present disclosure.

In some implementations, the autoencoder model 230 may be trained, at least in part, using an SLGAN 240 including a generator network 242 and a discriminator network 244. For instance, the decoding portion 234 of the autoencoder model 230 (e.g., decoding model) may be trained using the discriminator network 244 of the SLGAN. In some examples, the decoding portion 234 is the generator network 242 of the SLGAN 240. In some examples, the decoding portion 234 may be configured to generate a target recipe based on a provided encoding input (e.g., the encoding from the encoding portion 232 of the autoencoder 230). The discriminator network 244 within the SLGAN 240 may be used to train the decoding portion 234 of the autoencoder 230 to generate better target recipes by taking the output of the decoding portion 234 as input and providing feedback data to the decoding portion 234. As a result, the encoding portion 232 of the autoencoder model 230 may receive improved feedback and training from the decoding portion 234 based on the improved feedback and training of the decoding portion 234 from the SLGAN 240. Further, in some embodiments, the output 250 of the trained model 220 may be an encoding from the SLGAN 240 trained autoencoder model 230. In these embodiments, the encoding may be indicative of one or more characteristics of a semiconductor crystal from which semiconductor crystal data 210 is received, such as a similarity or anomaly of the semiconductor crystal. Additionally, in some embodiments, the encoding provided as output 250 from the autoencoder model 230 may be indicative of a feature or feature distribution of the semiconductor crystal associated with the semiconductor crystal data 210.

FIG. 4B depicts an example process 300 for modifying semiconductor crystal recipes according to examples aspect of the present disclosure. The process 300 includes receiving semiconductor crystal data 210 and providing the semiconductor crystal data 210 to a trained model 320 to produce an output 250. In some embodiments, the trained model 320 may be a machine-learned image translation model 330 trained using the SLGAN 240. For example, it may be beneficial to predict one or more crystal growth parameters (e.g., height, yield) based on images of the boule. The image translation model 330 may receive any input to the trained model 320 and perform one or more image processing procedures or transformations to generate the output 250. As an example, the image translation model 330 may receive as input a first image with a first set of associated information (e.g., metadata, embedded feature data, caption, etc.) and output a second image different from the first image with a second set of associated information that is enhanced compared to the first set of associated information. For instance, the first set of associated information may be associated with a first type of image (e.g., PL image), whereas the second set of associated information may be associated with a second type of image (e.g., birefringent cross-polarization image). In some examples, the first set of information may be associated with non-destructive data and the second set of information may be associated with destructive data. In some embodiments, based on the output 250, one or more characteristics of the semiconductor crystal associated with the semiconductor crystal data 210 may be determined.

In some embodiments, the image translation model may be trained using the SLGAN 240. The SLGAN may include a generator network 242 and a discriminator network 244. In some examples, the image translation model 330 may be the generator network 242. In some implementations, the discriminator network 244 of the SLGAN 240 may provide feedback data to the image translation model 330 during training to improve the output of the image translation model 330.

FIG. 4C depicts an example process 400 for modifying semiconductor crystal recipes according to examples aspect of the present disclosure. The example process 400 includes processing the semiconductor crystal data 210 with a trained model 420 to produce an output 250 associated with one or more characteristics of a semiconductor crystal associated with the semiconductor crystal data 210. In some implementations the trained model 420 includes a machine-learned feature detection model trained using the SLGAN 240. The feature detection model 430 may take any input to the trained model 420, such as semiconductor crystal data 210, and generate a feature detection output as output 250.

The feature detection output may include a variety of data and formats. For instance, in some implementations, the feature detection output may be a target recipe including one or more pixels associated with a feature or feature distribution of a semiconductor crystal associated with the semiconductor crystal data 210. For instance, pixels where a feature is detected may have a first value and pixels where a feature is not detected may have a second value that is different from the first value. Example features may include, but are not limited to, a threading edge dislocation, basal plan dislocation, threading screw dislocation, micropipe, mixed dislocation, hexagonal void, stacking fault, or scratch. Additionally, in some implementations, the feature detection output may include data indicative of one or more locations of a feature or feature distribution, classification of a feature or feature distribution, size of a feature or feature distribution, or shape of a feature or feature distribution. As an example, the feature detection model 430 may receive image data of at least a portion of a semiconductor crystal, such as one or more images, as input and output the image data with an identification of one or more features present within the image data, a classification of the features present (e.g., threading edge dislocation, basal plan dislocation, threading screw dislocation, etc.), and an image segmentation of each of the features present. In some embodiments, based on the output 250, one or more characteristics of the semiconductor crystal associated with the semiconductor crystal data 210 may be determined.

As illustrated in FIG. 4C, the feature detection model 430 may be trained using the SLGAN 240. The SLGAN may include a generator network 242 and a discriminator network 244. In some examples, the feature detection model 430 may be the generator network 242. In some implementations, the discriminator network 244 of the SLGAN 240 may provide feedback data to the feature detection model 430 during training to improve the output of the feature detection model 430.

FIG. 4D shows another exemplary process 450 of training and/or inferring using a machine learning model, according to some embodiments. This process may be done automatically in response to receiving the input data obtained by the crystal growth assembly 112, the controller 102, and/or the computing device 106.

The process 450 may include receiving an input 452 (e.g., from a crystal growth assembly 112, a controller 102, a human, a computing device 106), passing the input 452 through the trained machine learning model (e.g., a convolutional neural network (CNN)), and receiving an output 456. The input 452 may include one or more images, crystal growth parameters, and/or tensor data. The trained machine learning model receives the input 452 and passes it to one or more model layers 458. In some examples, the one or more model layers 458 may include hidden layers and a plurality of convolutional layers that “convolve” with a multiplication or other dot product. Additional convolutions may be included, such as pooling layers, fully connected layers, and normalization layers. One or more of these layers may be “hidden” layers because their inputs and outputs are masked by an activation function and a final convolution.

Pooling layers may reduce the dimensions of the data by combining the outputs of neuron clusters at one layer into a single neuron in the next layer. Pooling may be a form of non-linear down sampling. Pooling may compute a max or an average. Thus, pooling may provide a first approximation of a desired feature, such as a prediction of boule growth height or yield. For example, max pooling may use the maximum value from each of a cluster of neurons at a prior layer. By contrast, average pooling may use an average value from one or more clusters of neurons at the prior layer. It may be noted that maximum and average pooling are only examples, as other pooling types may be used. In some examples, the pooling layers transmit pooled data to fully connected layers.

Fully connected layers, such as a fully connected layer 460, may connect every neuron in one layer to every neuron in another layer. Thus, fully connected layers may operate like a multi-layer perceptron neural network (MLP). A resulting flattened matrix may pass through the fully connected layer 460 to classify the input 452.

At one or more convolutions, the process 450 may include a sliding dot product and/or a cross-correlation. Indices of a matrix at one or more convolutions or model layers 458 may be affected by weights in determining a specific index point. For example, each neuron in a neural network may compute an output value by applying a particular function to the input values coming from the receptive field in the previous layer. A vector of weights and/or a bias may determine a function that is applied to the input values. Thus, as the trained machine learning model proceeds through the model layers 458, iterative adjustments to these biases and weights results in a defined output 456, such as a location, orientation, or the like.

Weights may be applied based on one or more factors. For example, the weight of one or more objects and/or one or more layers within a CNN or other machine learning model may be based on data associated with the images. For example, the model layers 458 can apply a weight (e.g., to a parameter and/or parameter type) based on a parameter type associated with the crystal boule. For example, a higher weight may be applied to higher order (e.g., higher priority) crystal growth parameters than to lower order (e.g., lower priority) ones.

FIG. 4E depicts another example process 480 using a deep neural network. The deep neural network can optimize the crystal growth process by generating a modified crystal growth recipe. The process 480 begins with the deep neural network receiving an input 482. This input can include one or more crystal growth parameters, which may include variables such as temperature gradients, rotation speeds, atmospheric pressure, seed crystal orientation, initial doping concentrations, and/or any other parameter described herein. These parameters are valuable in determining the growth dynamics and quality of the resulting crystal.

The deep neural network includes a plurality of hidden layers 484, each containing a set of neurons 488. These hidden layers form the computational units of the deep neural network, where complex relationships between input parameters are analyzed and processed. Each neuron 488 in the hidden layers performs mathematical operations on the input data, applying weights and biases learned during training. The neurons 488 activate based on these computations, passing transformed data to subsequent layers of neurons 488.

As data progresses through the hidden layers 484, the deep neural network extracts higher-level features and patterns from the raw input. For instance, the deep neural network might learn to identify correlations between temperature gradients and defect rates or between rotation speeds and crystal uniformity. The hidden layers 484 can enable the deep neural network to generate non-linear relationships within the input data 482. The non-linear interactions between parameters can inform the final recipe, and therefore the quality, of the crystal.

Once the input has been processed through the hidden layers 484, the deep neural network produces an output 486. This output 486 can include a modified crystal growth recipe. The output recipe may include adjusted parameters such as refined temperature profiles, modified rotation schedules, altered doping concentrations, and/or other modified parameters.

The modified crystal growth recipe generated by the deep neural network can be transmitted to a crystal growth assembly, such as the crystal growth assembly 112. The crystal growth assembly 112 can be configured to execute the growth process according to the modified recipe. The updated recipe may be in real-time, allowing the crystal growth assembly 112 to adjust its operations to reflect the modified conditions generated by the deep neural network. In some embodiments, the crystal growth assembly 112 can include an imaging source (e.g., x-ray source) to monitor (e.g., in real-time) one or more aspects of the bulk crystal during the growth of the crystal. For example, the imaging source may include an x-ray source that can non-invasively probe a structure (e.g., internal structure) of the semiconductor crystal in real-time, even in high-temperature environments. For example, the x-ray source may identify a type and/or degree of crystal formation within the growing semiconductor crystal. This may allow the crystal growth assembly 112 to confirm that crystal formation has a character and/or quality that is desired. For example, the x-ray source may identify dislocations in the crystal lattice, stacking faults or other irregularities, and/or voids in the crystal lattice. In some embodiments, the x-ray source may be used for x-ray visualization to track vapor source (e.g., powder source, solid source) consumption and/or arrangement in connection with crystal quality (e.g., defects) and crystal height/shape to provide more information (e.g., training information) for machine learning optimization. In some embodiments, the crystal growth assembly 112 can control the height and/or convexity of the semiconductor crystal and/or a shape of the crystal vapor source in situ. For example, the crystal growth assembly 112 can include a seed graphite plate on the vapor source. X-ray visualization can be used to detect nucleation of poly-inclusion/parasitic 3C, 6H, etc. inclusions or other features on the crystal during growth. Additionally or alternatively, x-ray visualization can be used to track the vapor source (e.g., powder, solid) consumption and/or rearrangement in connection with crystal quality (e.g., defects, etc.) and/or crystal height/shape. In some embodiments, vapor source consumption may be monitored and/or improved using machine learning techniques described herein. Accordingly, the crystal growth assembly 112 can determine whether to terminate the growth of the crystal to save time and/or increase efficiency and/or can terminate the growth.

In some implementations, the crystal growth assembly 112 may provide feedback to the deep neural network, allowing it to further refine its predictions and improve future recipes. This feedback loop can enhance the network's accuracy over time.

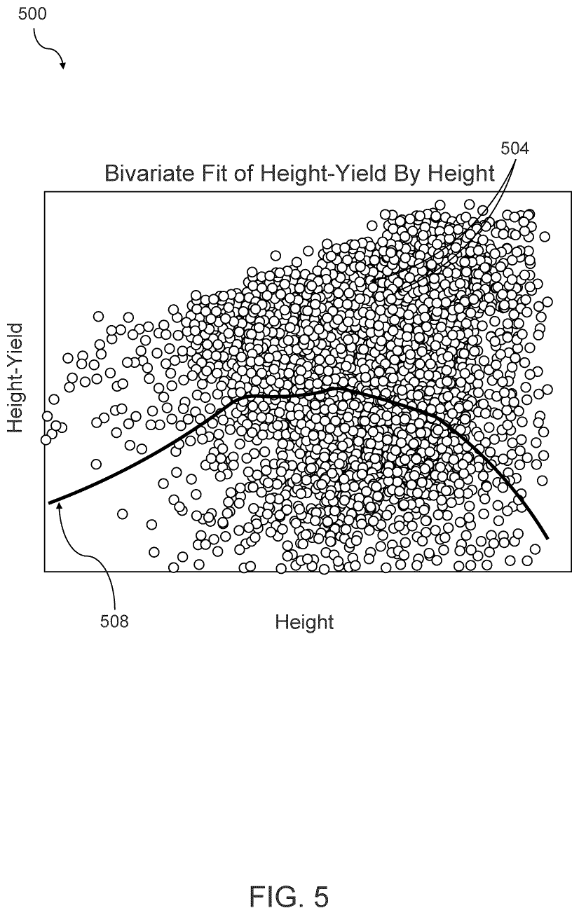

FIG. 5 shows an example yield-height plot 500 that may be developed using a large set of recipes. Such a set of recipes may be used to train one or more of the trained models described herein. As shown, the yield-height plot 500 includes a plurality of yield-height points 504. The yield-height points 504 may be used to generate a yield-height curve 508 across the height of the boule. It may be advantageous to achieve steep lines at the lowest and highest ends of the yield-height curve 508. Additionally or alternatively, it may be advantageous to achieve a relatively high, flat curve in the middle of the yield-height curve 508. This can indicate a high degree of yield for the height achieved.

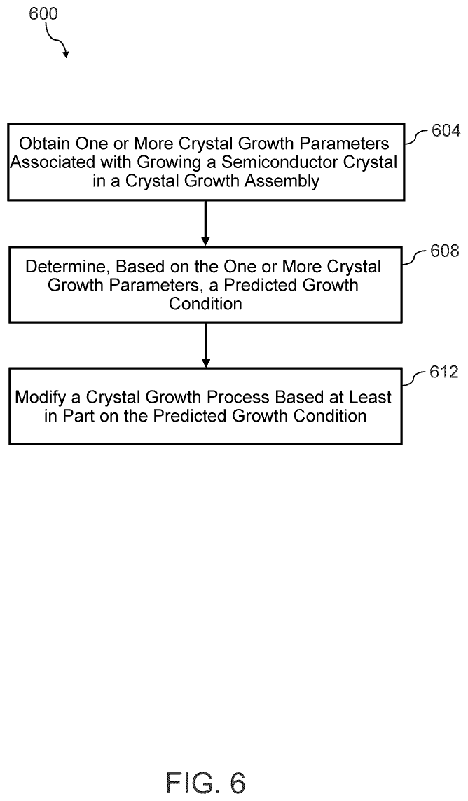

FIG. 6 depicts a flow chart diagram of an example method 600 according to example embodiments of the present disclosure. FIG. 6 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 604, the method 600 includes obtaining one or more crystal growth parameters associated with growing a semiconductor crystal in a crystal growth assembly. In some embodiments, one or more growth criteria includes the ratio of the predicted crystal yield to the predicted height of the semiconductor crystal.

The crystal growth parameters can include a crystal weight, a crystal convexity, a crystal resistivity, a number of defects in the semiconductor crystal, a topography of the semiconductor crystal, a type of a crucible of the crystal growth assembly, a type of a grower of the crystal growth assembly, a process condition, an age of the crucible, an age of the grower, an age of coils of the grower, an age of insulation of the grower, a temperature of water associated with growing the semiconductor crystal, a power type, a crystal growth rate, a crystallographic orientation, a purity, a surface quality, an optical property of the semiconductor crystal, and/or a hardness of the semiconductor crystal.

At 608, the method 600 includes determining, based on the one or more crystal growth parameters, a predicted growth condition. In some embodiments, determining the predicted growth condition includes determining a confidence level that the semiconductor crystal will satisfy one or more growth criteria. In some embodiments, the method 600 includes causing, based on the confidence level, the crystal growth assembly to modify the one or more crystal growth parameters. The confidence level may be based on a ratio of a predicted crystal yield to a predicted height of the semiconductor crystal.

In some embodiments, determining the predicted growth condition includes determining a predicted convexity of the semiconductor crystal. Additionally or alternatively, determining the predicted growth condition includes determining a predicted growth rate of the semiconductor crystal. In some embodiments, determining the predicted growth condition includes determining a predicted height of the semiconductor crystal.

In some embodiments, determining the predicted growth condition includes using a trained model associated with the crystal growth process. For example, using the trained model can include generating perturbations of at least one of the one or more crystal growth parameters. The trained model can include a convolutional neural network (CNN), a deep neural network (DNN), a Bayesian neural network (BNN), and/or any other trained model described herein. For example, the trained model can cause a randomized dropout of neural network connections (e.g., within the CNN). Additionally or alternatively, using the trained model can include generating a plurality of models each associated with a different weight assigned to a respective neural network connection.

At 612, the method 600 includes modifying a crystal growth process based at least in part on the predicted growth condition. In some embodiments, modifying the crystal growth process is further based on a predicted height of the semiconductor crystal. Additionally or alternatively, modifying the crystal growth process can include modifying a recipe of the crystal growth process. In some embodiments, modifying the crystal growth process is configured to reduce a predicted variance, within a height range, in a crystal yield as a function of the predicted height of the semiconductor crystal.

In some embodiments, the method 600 includes assigning each of a plurality of crucibles a respective identifier and/or assigning a respective grower to each of the plurality of crucibles. The method 600 may include selecting a first crucible and a first grower for the crystal growth assembly. In some examples, determining the predicted growth condition is further based on the first crucible and the first grower. Additionally or alternatively, modifying the crystal growth process can include selecting a second grower different from the first grower. For example, it may be beneficial to change a grower from a currently assigned grower, based on a predicted growth parameter.

In some embodiments, the method 600 includes growing, based on the one or more crystal growth parameters, the semiconductor crystal. This may be done using, for example, the crystal growth assembly 112. Additionally or alternatively, the method 600 may include measuring an actual growth condition of the semiconductor crystal. The system may compare the actual growth condition of the semiconductor crystal with the predicted growth condition. In some embodiments, modifying the crystal growth process is further based on comparing the actual growth condition of the semiconductor crystal with the predicted growth condition.

In some embodiments, the method 600 includes determining a crystal growth parameter of the one or more crystal growth parameters to modify. Determining the crystal growth parameter to modify may be based on determining that a predicted height of the semiconductor crystal is outside a target height range. In some embodiments, determining the crystal growth parameter to modify is based on determining that a predicted variance, within a height range, in a crystal yield as a function of a predicted height of the semiconductor crystal is outside a target variance range.

In some embodiments, modifying the crystal growth process includes modifying at least one of: a temperature of a grower, a flow of gas within the crystal growth assembly, a doping within the semiconductor crystal, a time of the semiconductor crystal within the grower, a placement of the semiconductor crystal within the grower, a pressure within the grower, or a position of a crucible of the crystal growth assembly relative to the grower. Additionally or alternatively, modifying the crystal growth process may include modifying a flow of nitrogen into the crystal growth assembly.

In some embodiments, the method 600 includes determining a temperature within the crystal growth assembly. Modifying the flow of nitrogen into the crystal growth assembly may be based on the temperature within the crystal growth assembly. The temperature within the crystal growth assembly can include a temperature of a crystal growth front of the semiconductor crystal.

The predicted growth condition can include a resistivity of the semiconductor crystal. Additionally or alternatively, modifying the crystal growth process may be configured to modify a concentration of nitrogen within the semiconductor crystal.

The one or more crystal growth parameters can include at least one of: a growth rate, a permeability of a crucible of the crystal growth assembly, a nitrogen concentration in the crystal growth assembly, and/or a concentration of a chemical compound configured to reduce an activation energy for nitrogen incorporation

In some embodiments, the method 600 includes modifying the concentration of nitrogen by modifying at least one of: a partial pressure of nitrogen in a gas within the crystal growth assembly, or a temperature of a crystal growth front of the semiconductor crystal. The semiconductor crystal can include a silicon carbide boule.

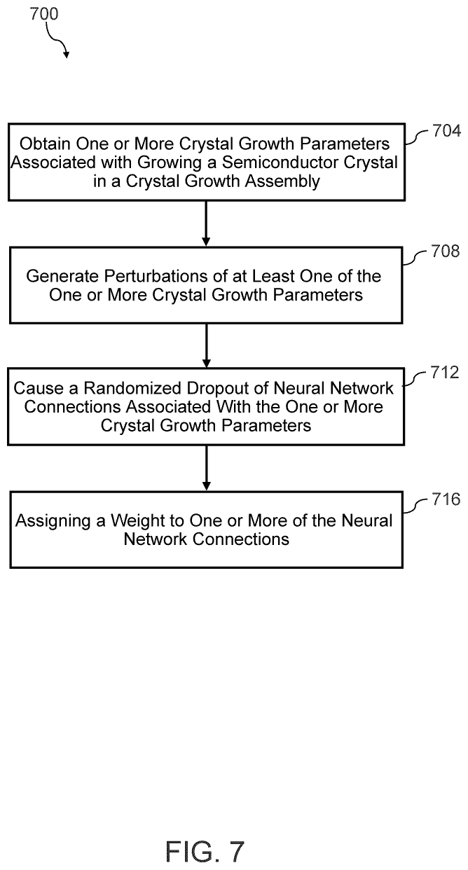

FIG. 7 depicts a flow chart diagram of an example method 700 according to example embodiments of the present disclosure. FIG. 7 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 704, the method 700 includes obtaining one or more crystal growth parameters associated with growing a semiconductor crystal in a crystal growth assembly. At 708, the method 700 includes generating perturbations of at least one of the one or more crystal growth parameters. This may be done, for example, using a trained model described herein. At 712, the method 700 includes causing a randomized dropout of neural network connections associated with the one or more crystal growth parameters. At 716, the method 700 includes assigning a weight to one or more of the neural network connections.

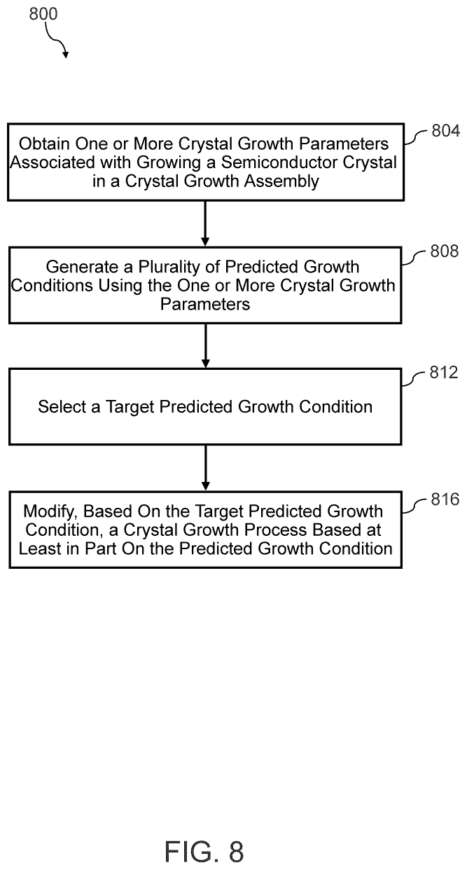

FIG. 8 depicts a flow chart diagram of an example method 800 according to example embodiments of the present disclosure. FIG. 8 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 804, the method 800 includes obtaining one or more crystal growth parameters associated with growing a semiconductor crystal in a crystal growth assembly. At 808, the method 800 includes generating a plurality of predicted growth conditions using the one or more crystal growth parameters. At 812, the method 800 includes selecting a target predicted growth condition. At 816, the method 800 includes modifying, based on the target predicted growth condition, a crystal growth process based at least in part on the predicted growth condition.

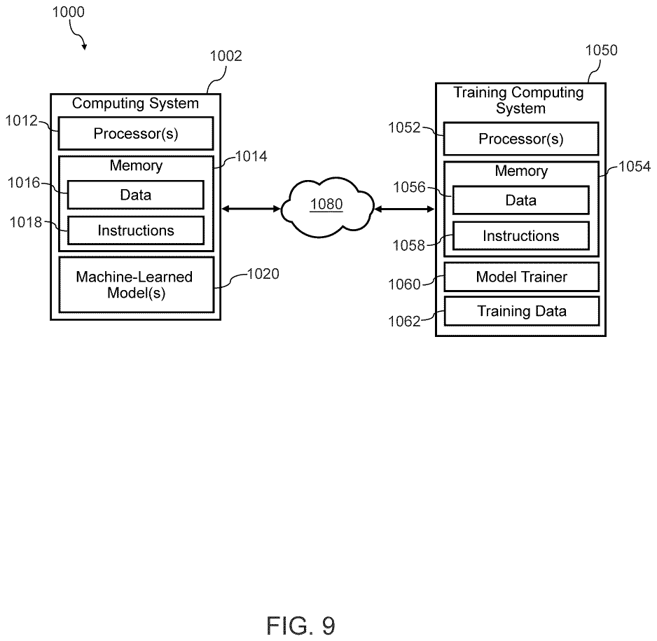

FIG. 9 depicts a block diagram of an example computing system 1000 that can be used to implement systems and methods according to example embodiments of the present disclosure. The system 1000 includes a computing system 1002 and a training computing system 1050 that are communicatively coupled over a network 1080.

The computing system 1002 can include any type of computing device (e.g., classical and/or quantum computing device). The computing system 1002 includes one or more processors 1012 and a memory 1014. The one or more processors 1012 can be any suitable processing device (e.g., a processor core, a microprocessor, CPU, GPU, an ASIC, a FPGA, a controller, a microcontroller, etc.) and can be one processor or a plurality of processors that are operatively connected. The memory 1014 can include one or more non-transitory computer-readable storage mediums, such as RAM, ROM, EEPROM, EPROM, flash memory devices, magnetic disks, etc., and combinations thereof. The memory 1014 can store data 1016 (e.g., parameters, input data, etc.) and instructions 1018 which are executed by the processor 1012 to cause the computing system 1002 to perform operations. In some implementations, the computing system 1002 can store or include one or more machine-learned models 1020 (e.g., autoencoders, machine-learned encoding models, etc.) as described herein.

The computing system 1002 can train the machine-learned model(s) 1020 via interaction with the training computing system 1050 that is communicatively coupled over the network 1080. The training computing system 1050 can be separate from the computing system 1002 or can be a portion of the computing system 1002.

The training computing system 1050 includes one or more processors 1052 and a memory 1054. The one or more processors 1052 can be any suitable processing device (e.g., a processor core, a microprocessor, CPU, GPU, an ASIC, a FPGA, a controller, a microcontroller, etc.) and can be one processor or a plurality of processors that are operatively connected. The memory 1054 can include one or more non-transitory computer-readable storage mediums, such as RAM, ROM, EEPROM, EPROM, flash memory devices, magnetic disks, etc., and combinations thereof. The memory 1054 can store data 1056 and instructions 1058 which are executed by the processor 1052 to cause the training computing system 1050 to perform operations. In some implementations, the training computing system 1050 includes or is otherwise implemented by one or more server computing devices.

The training computing system 1050 can include a model trainer 1060 that trains the machine-learned model(s) 1020 using various training or learning techniques, such as, for example, backwards propagation of errors. In some implementations, performing backwards propagation of errors can include performing truncated backpropagation through time. The model trainer 1060 can perform a number of generalization techniques (e.g., weight decays, dropouts, etc.) to improve the generalization capability of the models being trained.

In particular, the model trainer 1060 can train the machine-learned model(s) 1020 based on a set of training data 1062. The training data 1062 can include, for example, input data corresponding to a plurality of semiconductor workpieces workpiece images, time series data, tabular data, etc.

The model trainer 1060 includes computer logic utilized to provide desired functionality. The model trainer 1060 can be implemented in hardware, firmware, and/or software controlling a general purpose processor. For example, in some implementations, the model trainer 1060 includes program files stored on a storage device, loaded into a memory and executed by one or more processors. In other implementations, the model trainer 1060 includes one or more sets of computer-executable instructions that are stored in a tangible computer-readable storage medium such as RAM hard disk or optical or magnetic media.

The network 1080 can be any type of communications network, such as a local area network (e.g., intranet), wide area network (e.g., Internet), or some combination thereof and can include any number of wired or wireless links. In general, communication over the network 1080 can be carried via any type of wired and/or wireless connection, using a wide variety of communication protocols (e.g., TCP/IP, HTTP, SMTP, FTP), encodings or formats (e.g., HTML, XML), and/or protection schemes (e.g., VPN, secure HTTP, SSL).

FIG. 9 illustrates one example computing system that can be used to implement example aspects of the present disclosure. Other computing systems can be used as well. For example, in some implementations, the computing system 1002 can include the model trainer 1060 and the training data 1062. In such implementations, the model(s) 1020 can be both trained and used locally at the computing system 1002.

The technology discussed herein makes reference to servers, databases, software applications, and other computer-based systems, as well as actions taken and information sent to and from such systems. The inherent flexibility of computer-based systems allows for a great variety of possible configurations, combinations, and divisions of tasks and functionality between and among components. For instance, processes discussed herein can be implemented using a single device or component or multiple devices or components working in combination. Databases and applications can be implemented on a single system or distributed across multiple systems. Distributed components can operate sequentially or in parallel.

Example aspects of the present disclosure are set forth below. Any of the below features or examples may be used in combination with any of the embodiments or features provided in the present disclosure.

In some implementations of the example method, the example method includes: obtaining one or more crystal growth parameters associated with growing a semiconductor crystal in a crystal growth assembly; determining, based on the one or more crystal growth parameters, a predicted growth condition; and modifying a crystal growth process based at least in part on the predicted growth condition.

In some implementations of the example method, determining the predicted growth condition includes determining a confidence level that the semiconductor crystal will satisfy one or more growth criteria.

In some implementations of the example method includes causing, based on the confidence level, the crystal growth assembly to modify the one or more crystal growth parameters.

In some implementations of the example method, the confidence level is based on a ratio of a predicted crystal yield to a predicted height of the semiconductor crystal.

In some implementations of the example method, modifying the crystal growth process is further based on a predicted height of the semiconductor crystal.

In some implementations of the example method, at least one of the one or more growth criteria includes the ratio of the predicted crystal yield to the predicted height of the semiconductor crystal.

In some implementations of the example method, the one or more crystal growth parameters comprise at least one of: a crystal weight, a crystal convexity, a crystal resistivity, a number of defects in the semiconductor crystal, a topography of the semiconductor crystal, a type of a crucible of the crystal growth assembly, a type of a grower of the crystal growth assembly, a process condition, an age of the crucible, an age of the grower, an age of coils of the grower, an age of insulation of the grower, a temperature of water associated with growing the semiconductor crystal, a power type, a crystal growth rate, a crystallographic orientation, a purity, a surface quality, an optical property of the semiconductor crystal, or a hardness of the semiconductor crystal.

In some implementations of the example method, modifying the crystal growth process includes modifying a recipe of the crystal growth process.

In some implementations of the example method includes assigning each of a plurality of crucibles a respective identifier.

The method of claim 9, further comprising: assigning a respective grower to each of the plurality of crucibles.

In some implementations of the example method includes selecting a first crucible and a first grower for the crystal growth assembly.

In some implementations of the example method, determining the predicted growth condition is further based on the first crucible and the first grower.

In some implementations of the example method, modifying the crystal growth process includes selecting a second grower different from the first grower.

In some implementations of the example method, determining the predicted growth condition includes determining a predicted convexity of the semiconductor crystal.

In some implementations of the example method, determining the predicted growth condition includes determining a predicted growth rate of the semiconductor crystal.

In some implementations of the example method, determining the predicted growth condition includes determining a predicted height of the semiconductor crystal.

In some implementations of the example method, modifying the crystal growth process is configured to reduce a predicted variance, within a height range, in a crystal yield as a function of the predicted height of the semiconductor crystal.

In some implementations of the example method, determining the predicted growth condition includes using a trained model associated with the crystal growth process.

In some implementations of the example method, using the trained model includes generating perturbations of at least one of the one or more crystal growth parameters.

In some implementations of the example method, the trained model includes a convolutional neural network (CNN).

In some implementations of the example method, using the trained model includes causing a randomized dropout of neural network connections within the CNN.

In some implementations of the example method, using the trained model includes generating a plurality of models each associated with a different weight assigned to a respective neural network connection.

In some implementations of the example method includes growing, based on the one or more crystal growth parameters, the semiconductor crystal.

In some implementations of the example method includes measuring an actual growth condition of the semiconductor crystal.

In some implementations of the example method includes comparing the actual growth condition of the semiconductor crystal with the predicted growth condition.

In some implementations of the example method, modifying the crystal growth process is further based on comparing the actual growth condition of the semiconductor crystal with the predicted growth condition.

In some implementations of the example method includes determining a crystal growth parameter of the one or more crystal growth parameters to modify.

In some implementations of the example method, determining the crystal growth parameter to modify is based on determining that a predicted height of the semiconductor crystal is outside a target height range.

In some implementations of the example method, determining the crystal growth parameter to modify is based on determining that a predicted variance, within a height range, in a crystal yield as a function of a predicted height of the semiconductor crystal is outside a target variance range.

In some implementations of the example method, modifying the crystal growth process includes modifying at least one of: a temperature of a grower, a flow of gas within the crystal growth assembly, a doping within the semiconductor crystal, a time of the semiconductor crystal within the grower, a placement of the semiconductor crystal within the grower, a pressure within the grower, or a position of a crucible of the crystal growth assembly relative to the grower.

In some implementations of the example method, modifying the crystal growth process includes modifying a flow of nitrogen into the crystal growth assembly.

In some implementations of the example method includes determining a temperature within the crystal growth assembly.

In some implementations of the example method, modifying the flow of nitrogen into the crystal growth assembly is based on the temperature within the crystal growth assembly.

In some implementations of the example method, the temperature within the crystal growth assembly includes a temperature of a crystal growth front of the semiconductor crystal.

In some implementations of the example method, the predicted growth condition includes a resistivity of the semiconductor crystal.

In some implementations of the example method, modifying the crystal growth process is configured to modify a concentration of nitrogen within the semiconductor crystal.

In some implementations of the example method, the one or more crystal growth parameters comprise at least one of: a growth rate, a permeability of a crucible of the crystal growth assembly, a nitrogen concentration in the crystal growth assembly, or a concentration of a chemical compound configured to reduce an activation energy for nitrogen incorporation.

In some implementations of the example method includes modifying the concentration of nitrogen by modifying at least one of: a partial pressure of nitrogen in a gas within the crystal growth assembly, or a temperature of a crystal growth front of the semiconductor crystal.

In some implementations of the example method, the semiconductor crystal includes a silicon carbide boule.

In some implementations of the example method includes imaging, using an x-ray source, the semiconductor crystal in real-time.

In some implementations of the example method, modifying the crystal growth process is further based on the imaging of the semiconductor crystal.

In some implementations of the example method, the present disclosure provides an example system one or more computer readable storage devices configured to store computer-executable instructions; and one or more hardware computer processors in communication with the one or more computer readable storage devices and configured to execute the computer-executable instructions to: obtain one or more crystal growth parameters associated with growing a semiconductor crystal in a crystal growth assembly; determine, based on the one or more crystal growth parameters, a predicted growth condition; and modify a crystal growth process based at least in part on the predicted growth condition.

In some implementations of the example system, determining the predicted growth condition includes determining a confidence level that the semiconductor crystal will satisfy one or more growth criteria.

In some implementations of the example method, the one or more hardware computer processors are configured to execute the computer-executable instructions further to: causing, based on the confidence level, the crystal growth assembly to modify the one or more crystal growth parameters.

In some implementations of the example system, the confidence level is based on a ratio of a predicted crystal yield to a predicted height of the semiconductor crystal.

In some implementations of the example system, modifying the crystal growth process is further based on a predicted height of the semiconductor crystal.

In some implementations of the example system, at least one of the one or more growth criteria includes the ratio of the predicted crystal yield to the predicted height of the semiconductor crystal.

In some implementations of the example system, the one or more crystal growth parameters comprise at least one of: a crystal weight, a crystal convexity, a crystal resistivity, a number of defects in the semiconductor crystal, a topography of the semiconductor crystal, a type of a crucible of the crystal growth assembly, a type of a grower of the crystal growth assembly, a process condition, an age of the crucible, an age of the grower, an age of coils of the grower, an age of insulation of the grower, a temperature of water associated with growing the semiconductor crystal, a power type, a crystal growth rate, a crystallographic orientation, a purity, a surface quality, an optical property of the semiconductor crystal, or a hardness of the semiconductor crystal.

In some implementations of the example system, modifying the crystal growth process includes modifying a recipe of the crystal growth process.

In some implementations of the example method, the one or more hardware computer processors are configured to execute the computer-executable instructions further to: assigning each of a plurality of crucibles a respective identifier.

In some implementations of the example method, the one or more hardware computer processors are configured to execute the computer-executable instructions further to: assigning a respective grower to each of the plurality of crucibles.

In some implementations of the example method, the one or more hardware computer processors are configured to execute the computer-executable instructions further to: selecting a first crucible and a first grower for the crystal growth assembly.

In some implementations of the example system, determining the predicted growth condition is further based on the first crucible and the first grower.

In some implementations of the example system, modifying the crystal growth process includes selecting a second grower different from the first grower.

In some implementations of the example system, determining the predicted growth condition includes determining a predicted convexity of the semiconductor crystal.

In some implementations of the example system, determining the predicted growth condition includes determining a predicted growth rate of the semiconductor crystal.

In some implementations of the example system, determining the predicted growth condition includes determining a predicted height of the semiconductor crystal.

In some implementations of the example system, modifying the crystal growth process is configured to reduce a predicted variance, within a height range, in a crystal yield as a function of the predicted height of the semiconductor crystal.

In some implementations of the example system, the one or more computer readable storage devices is further configured to store a trained model associated with the crystal growth process, and wherein determining the predicted growth condition includes using the trained model.

In some implementations of the example system, using the trained model includes generating perturbations of at least one of the one or more crystal growth parameters.

In some implementations of the example system, the trained model includes a convolutional neural network (CNN).

In some implementations of the example system, using the trained model includes causing a randomized dropout of neural network connections within the CNN.

In some implementations of the example system, using the trained model includes generating a plurality of models each associated with a different weight assigned to a respective neural network connection.

In some implementations of the example method, the one or more hardware computer processors are configured to execute the computer-executable instructions further to: growing, based on the one or more crystal growth parameters, the semiconductor crystal.

In some implementations of the example method, the one or more hardware computer processors are configured to execute the computer-executable instructions further to: measuring an actual growth condition of the semiconductor crystal.

In some implementations of the example method, the one or more hardware computer processors are configured to execute the computer-executable instructions further to: comparing the actual growth condition of the semiconductor crystal with the predicted growth condition.

In some implementations of the example system, modifying the crystal growth process is further based on comparing the actual growth condition of the semiconductor crystal with the predicted growth condition.

In some implementations of the example method, the one or more hardware computer processors are configured to execute the computer-executable instructions further to: determining a crystal growth parameter of the one or more crystal growth parameters to modify.

In some implementations of the example system, determining the crystal growth parameter to modify is based on determining that a predicted height of the semiconductor crystal is outside a target height range.

In some implementations of the example system, determining the crystal growth parameter to modify is based on determining that a predicted variance, within a height range, in a crystal yield as a function of a predicted height of the semiconductor crystal is outside a target variance range.

In some implementations of the example system, modifying the crystal growth process includes modifying at least one of: a temperature of a grower, a flow of gas within the crystal growth assembly, a doping within the semiconductor crystal, a time of the semiconductor crystal within the grower, a placement of the semiconductor crystal within the grower, a pressure within the grower, or a position of a crucible of the crystal growth assembly relative to the grower.

In some implementations of the example system, modifying the crystal growth process includes modifying a flow of nitrogen into the crystal growth assembly.

In some implementations of the example method, the one or more hardware computer processors are configured to execute the computer-executable instructions further to: determining a temperature within the crystal growth assembly.

In some implementations of the example system, modifying the flow of nitrogen into the crystal growth assembly is based on the temperature within the crystal growth assembly.

In some implementations of the example system, the temperature within the crystal growth assembly includes a temperature of a crystal growth front of the semiconductor crystal.

In some implementations of the example system, the predicted growth condition includes a resistivity of the semiconductor crystal.

In some implementations of the example system, modifying the crystal growth process is configured to modify a concentration of nitrogen within the semiconductor crystal.

In some implementations of the example system, the one or more crystal growth parameters comprise at least one of: a growth rate, a permeability of a crucible of the crystal growth assembly, a nitrogen concentration in the crystal growth assembly, or a concentration of a chemical compound configured to reduce an activation energy for nitrogen incorporation.

In some implementations of the example method, the one or more hardware computer processors are configured to execute the computer-executable instructions further to: modifying the concentration of nitrogen by modifying at least one of: a partial pressure of nitrogen in a gas within the crystal growth assembly, or a temperature of a crystal growth front of the semiconductor crystal.

In some implementations of the example system, the semiconductor crystal includes a silicon carbide boule.

In some implementations of the example system further including an x-ray source, the one or more hardware computer processors are configured to execute the computer-executable instructions further to: imaging, using the x-ray source, the semiconductor crystal in real-time.

In some implementations of the example system, modifying the crystal growth process is further based on the imaging of the semiconductor crystal.

In some implementations of the example method, the method includes obtaining one or more crystal growth parameters associated with growing a semiconductor crystal in a crystal growth assembly; generating perturbations of at least one of the one or more crystal growth parameters; causing a randomized dropout of neural network connections associated with the one or more crystal growth parameters; and assigning a weight to one or more of the neural network connections.

In some implementations of the example method, the method includes generating a plurality of models each associated with a different weight assigned to a respective neural network connection.

In some implementations of the example method, obtaining one or more crystal growth parameters includes determining a confidence level that the semiconductor crystal will satisfy one or more growth criteria.

In some implementations of the example method, the method includes causing, based on the confidence level, the crystal growth assembly to modify the one or more crystal growth parameters.

In some implementations of the example method, the confidence level is based on a ratio of a predicted crystal yield to a predicted height of the semiconductor crystal.

In some implementations of the example method, the method includes modifying a crystal growth process based at least in part on the weight to one or more of the neural network connections.

In some implementations of the example method, the method includes predicting, based on the confidence level, a height of the semiconductor crystal.

In some implementations of the example method, the method includes modifying a crystal growth process based at least in part on the predicted height of the semiconductor crystal.

In some implementations of the example method, at least one of the one or more growth criteria includes the ratio of the predicted crystal yield to the predicted height of the semiconductor crystal.

In some implementations of the example method, the one or more crystal growth parameters comprise at least one of: a crystal weight, a crystal convexity, a crystal resistivity, a number of defects in the semiconductor crystal, a topography of the semiconductor crystal, a type of a crucible of the crystal growth assembly, a type of a grower of the crystal growth assembly, a process condition, an age of the crucible, an age of the grower, an age of coils of the grower, an age of insulation of the grower, a temperature of water associated with growing the semiconductor crystal, a power type, a crystal growth rate, a crystallographic orientation, a purity, a surface quality, an optical property of the semiconductor crystal, or a hardness of the semiconductor crystal.

In some implementations of the example method, modifying the crystal growth process includes modifying a recipe of the crystal growth process.

In some implementations of the example method, the method includes assigning each of a plurality of crucibles a respective identifier.

In some implementations of the example method, the method includes assigning a respective grower to each of the plurality of crucibles.

In some implementations of the example method, the method includes selecting a first crucible and a first grower for the crystal growth assembly.

In some implementations of the example method, obtaining one or more crystal growth parameters is further based on the first crucible and the first grower.

In some implementations of the example method, modifying the crystal growth process includes selecting a second grower different from a first grower.

In some implementations of the example method, obtaining one or more crystal growth parameters includes determining a predicted convexity of the semiconductor crystal.

In some implementations of the example method, obtaining one or more crystal growth parameters includes determining a predicted growth rate of the semiconductor crystal.

In some implementations of the example method, obtaining one or more crystal growth parameters includes determining a predicted height of the semiconductor crystal.

In some implementations of the example method, modifying the crystal growth process is configured to reduce a predicted variance, within a height range, in a crystal yield as a function of the predicted height of the semiconductor crystal.

In some implementations of the example method, obtaining one or more crystal growth parameters includes using the trained model associated with the crystal growth process.

In some implementations of the example method, using the trained model includes generating perturbations of at least one of the one or more crystal growth parameters.

In some implementations of the example method, the trained model includes a convolutional neural network (CNN).

In some implementations of the example method, using the trained model includes generating a plurality of models each associated with a different weight assigned to a respective neural network connection.

In some implementations of the example method, the method includes growing, based on the one or more crystal growth parameters, the semiconductor crystal.

In some implementations of the example method, the method includes measuring an actual growth condition of the semiconductor crystal.

In some implementations of the example method, the method includes comparing the actual growth condition of the semiconductor crystal with an predicted growth condition.

In some implementations of the example method, obtaining one or more crystal growth parameters is further based on comparing the actual growth condition of the semiconductor crystal with the predicted growth condition.

In some implementations of the example method, the method includes determining a crystal growth parameter of the one or more crystal growth parameters to modify.

In some implementations of the example method, determining the crystal growth parameter to modify is based on determining that a predicted height of the semiconductor crystal is outside a target height range.

In some implementations of the example method, determining the crystal growth parameter to modify is based on determining that a predicted variance, within a height range, in a crystal yield as a function of a predicted height of the semiconductor crystal is outside a target variance range.

In some implementations of the example method, modifying the crystal growth process includes modifying at least one of: a temperature of a grower, a flow of gas within the crystal growth assembly, a doping within the semiconductor crystal, a time of the semiconductor crystal within the grower, a placement of the semiconductor crystal within the grower, a pressure within the grower, or a position of a crucible of the crystal growth assembly relative to the grower.

In some implementations of the example method, modifying the crystal growth process includes modifying a flow of nitrogen into the crystal growth assembly.

In some implementations of the example method, the method includes determining a temperature within the crystal growth assembly.

In some implementations of the example method, modifying the flow of nitrogen into the crystal growth assembly is based on the temperature within the crystal growth assembly.

In some implementations of the example method, the temperature within the crystal growth assembly includes a temperature of a crystal growth front of the semiconductor crystal.

In some implementations of the example method, the predicted growth condition includes a resistivity of the semiconductor crystal.

In some implementations of the example method, modifying the crystal growth process is configured to modify a concentration of nitrogen within the semiconductor crystal.

In some implementations of the example method, the one or more crystal growth parameters comprise at least one of: a growth rate, a permeability of a crucible of the crystal growth assembly, a nitrogen concentration in the crystal growth assembly, or a concentration of a chemical compound configured to reduce an activation energy for nitrogen incorporation.

In some implementations of the example method, the method includes modifying the concentration of nitrogen by modifying at least one of: a partial pressure of nitrogen in a gas within the crystal growth assembly, or a temperature of a crystal growth front of the semiconductor crystal.

In some implementations of the example method, the semiconductor crystal includes a silicon carbide boule.

In some implementations of the example method, the method includes imaging, using an x-ray source, the semiconductor crystal in real-time.

In some implementations of the example method, modifying the crystal growth process is further based on the imaging of the semiconductor crystal.

In some implementations of the example method, the method includes obtaining one or more crystal growth parameters associated with growing a semiconductor crystal in a crystal growth assembly; generating a plurality of predicted growth conditions using the one or more crystal growth parameters; selecting a target predicted growth condition; and modifying, based on the target predicted growth condition, a crystal growth process based at least in part on the predicted growth condition.

In some implementations of the example method, generating the plurality of predicted growth conditions includes determining a confidence level that the semiconductor crystal will satisfy one or more growth criteria.

In some implementations of the example method, the method includes causing, based on the confidence level, the crystal growth assembly to modify the one or more crystal growth parameters.

In some implementations of the example method, the confidence level is based on a ratio of a predicted crystal yield to a predicted height of the semiconductor crystal.

In some implementations of the example method, modifying the crystal growth process is further based on a predicted height of the semiconductor crystal.

In some implementations of the example method, at least one of the one or more growth criteria includes the ratio of the predicted crystal yield to the predicted height of the semiconductor crystal.

In some implementations of the example method, the one or more crystal growth parameters comprise at least one of: a crystal weight, a crystal convexity, a crystal resistivity, a number of defects in the semiconductor crystal, a topography of the semiconductor crystal, a type of a crucible of the crystal growth assembly, a type of a grower of the crystal growth assembly, a process condition, an age of the crucible, an age of the grower, an age of coils of the grower, an age of insulation of the grower, a temperature of water associated with growing the semiconductor crystal, a power type, a crystal growth rate, a crystallographic orientation, a purity, a surface quality, an optical property of the semiconductor crystal, or a hardness of the semiconductor crystal.

In some implementations of the example method, modifying the crystal growth process includes modifying a recipe of the crystal growth process.

In some implementations of the example method, the method includes assigning each of a plurality of crucibles a respective identifier.

In some implementations of the example method, the method includes assigning a respective grower to each of the plurality of crucibles.

In some implementations of the example method, the method includes selecting a first crucible and a first grower for the crystal growth assembly.

In some implementations of the example method, determining the predicted growth condition is further based on the first crucible and the first grower.

In some implementations of the example method, modifying the crystal growth process includes selecting a second grower different from the first grower.

In some implementations of the example method, generating the plurality of predicted growth conditions includes determining a predicted convexity of the semiconductor crystal.

In some implementations of the example method, generating the plurality of predicted growth conditions includes determining a predicted growth rate of the semiconductor crystal.

In some implementations of the example method, generating the plurality of predicted growth conditions includes determining a predicted height of the semiconductor crystal.

In some implementations of the example method, modifying the crystal growth process is configured to reduce a predicted variance, within a height range, in a crystal yield as a function of the predicted height of the semiconductor crystal.

In some implementations of the example method, generating the plurality of predicted growth conditions includes using a trained model associated with the crystal growth process.

In some implementations of the example method, using the trained model includes generating perturbations of at least one of the one or more crystal growth parameters.

In some implementations of the example method, the trained model includes a convolutional neural network (CNN).

In some implementations of the example method, using the trained model includes causing a randomized dropout of neural network connections within the CNN.

In some implementations of the example method, using the trained model includes generating a plurality of models each associated with a different weight assigned to a respective neural network connection.

In some implementations of the example method, the method includes growing, based on the one or more crystal growth parameters, the semiconductor crystal.

In some implementations of the example method, the method includes measuring an actual growth condition of the semiconductor crystal.

In some implementations of the example method, the method includes comparing the actual growth condition of the semiconductor crystal with the predicted growth condition.

In some implementations of the example method, modifying the crystal growth process is further based on comparing the actual growth condition of the semiconductor crystal with the predicted growth condition.

In some implementations of the example method, the method includes determining a crystal growth parameter of the one or more crystal growth parameters to modify.

In some implementations of the example method, determining the crystal growth parameter to modify is based on determining that a predicted height of the semiconductor crystal is outside a target height range.

In some implementations of the example method, determining the crystal growth parameter to modify is based on determining that a predicted variance, within a height range, in a crystal yield as a function of a predicted height of the semiconductor crystal is outside a target variance range.

In some implementations of the example method, modifying the crystal growth process includes modifying at least one of: a temperature of a grower, a flow of gas within the crystal growth assembly, a doping within the semiconductor crystal, a time of the semiconductor crystal within the grower, a placement of the semiconductor crystal within the grower, a pressure within the grower, or a position of a crucible of the crystal growth assembly relative to the grower.

In some implementations of the example method, modifying the crystal growth process includes modifying a flow of nitrogen into the crystal growth assembly.

In some implementations of the example method, the method includes determining a temperature within the crystal growth assembly.

In some implementations of the example method, modifying the flow of nitrogen into the crystal growth assembly is based on the temperature within the crystal growth assembly.

In some implementations of the example method, the temperature within the crystal growth assembly includes a temperature of a crystal growth front of the semiconductor crystal.

In some implementations of the example method, the predicted growth condition includes a resistivity of the semiconductor crystal.

In some implementations of the example method, modifying the crystal growth process is configured to modify a concentration of nitrogen within the semiconductor crystal.

In some implementations of the example method, the one or more crystal growth parameters comprise at least one of: a growth rate, a permeability of a crucible of the crystal growth assembly, a nitrogen concentration in the crystal growth assembly, or a concentration of a chemical compound configured to reduce an activation energy for nitrogen incorporation.

In some implementations of the example method, the method includes modifying the concentration of nitrogen by modifying at least one of: a partial pressure of nitrogen in a gas within the crystal growth assembly, or a temperature of a crystal growth front of the semiconductor crystal.

In some implementations of the example method, the semiconductor crystal includes a silicon carbide boule.

In some implementations of the example method, the method includes imaging, using an x-ray source, the semiconductor crystal in real-time.

In some implementations of the example method, modifying the crystal growth process is further based on the imaging of the semiconductor crystal.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method comprising:
obtaining one or more crystal growth parameters associated with growing a semiconductor crystal in a crystal growth assembly;
determining, based on the one or more crystal growth parameters, a predicted growth condition; and
modifying a crystal growth process based at least in part on the predicted growth condition.

2. The method of claim 1, wherein determining the predicted growth condition comprises determining a confidence level that the semiconductor crystal will satisfy one or more growth criteria.

3. The method of claim 2, further comprising:
causing, based on the confidence level, the crystal growth assembly to modify the one or more crystal growth parameters.

4. The method of claim 2, wherein the confidence level is based on a ratio of a predicted crystal yield to a predicted height of the semiconductor crystal.

5. The method of claim 2, wherein modifying the crystal growth process is further based on a predicted height of the semiconductor crystal.

6. The method of claim 4, wherein at least one of the one or more growth criteria comprises the ratio of the predicted crystal yield to the predicted height of the semiconductor crystal.

7. The method of claim 1, wherein the one or more crystal growth parameters comprise at least one of: a crystal weight, a crystal convexity, a crystal resistivity, a number of defects in the semiconductor crystal, a topography of the semiconductor crystal, a type of a crucible of the crystal growth assembly, a type of a grower of the crystal growth assembly, a process condition, an age of the crucible, an age of the grower, an age of coils of the grower, an age of insulation of the grower, a temperature of water associated with growing the semiconductor crystal, a power type, a crystal growth rate, a crystallographic orientation, a purity, a surface quality, an optical property of the semiconductor crystal, or a hardness of the semiconductor crystal.

8. The method of claim 1, wherein modifying the crystal growth process comprises modifying a recipe of the crystal growth process.

9. The method of claim 1, further comprising:
assigning each of a plurality of crucibles a respective identifier.

10. The method of claim 9, further comprising:
assigning a respective grower to each of the plurality of crucibles.

11. The method of claim 10, further comprising:
selecting a first crucible and a first grower for the crystal growth assembly.

12. The method of claim 11, wherein determining the predicted growth condition is further based on the first crucible and the first grower.

13. The method of claim 11, wherein modifying the crystal growth process comprises selecting a second grower different from the first grower.

14. The method of claim 1, wherein determining the predicted growth condition comprises determining a predicted convexity of the semiconductor crystal.

15. The method of claim 1, wherein determining the predicted growth condition comprises determining a predicted growth rate of the semiconductor crystal.

16. The method of claim 1, wherein determining the predicted growth condition comprises determining a predicted height of the semiconductor crystal.

17. The method of claim 16, wherein modifying the crystal growth process is configured to reduce a predicted variance, within a height range, in a crystal yield as a function of the predicted height of the semiconductor crystal.

18. A semiconductor crystal control system, the system comprising:
one or more computer readable storage devices configured to store computer-executable instructions; and
one or more hardware computer processors in communication with the one or more computer readable storage devices and configured to execute the computer-executable instructions to:
obtain one or more crystal growth parameters associated with growing a semiconductor crystal in a crystal growth assembly;
determine, based on the one or more crystal growth parameters, a predicted growth condition; and
modify a crystal growth process based at least in part on the predicted growth condition.

19. The system of claim 18, wherein determining the predicted growth condition comprises determining a confidence level that the semiconductor crystal will satisfy one or more growth criteria.

20. The system of claim 19, wherein the one or more hardware computer processors are configured to execute the computer-executable instructions further to:
causing, based on the confidence level, the crystal growth assembly to modify the one or more crystal growth parameters.
